(19) United States
(12) Patent Application Publication
(10) Pub. No.: US 2024/0170521 A1
(43) Pub. Date: May 23, 2024

(54) IMAGE SENSOR

(71) Applicant: SAMSUNG ELECTRONICS CO., LTD., Suwon-si (KR)

(72) Inventors: Kook Tae KIM, Suwon-si (KR); Jingyun KIM, Suwon-si (KR); Byeongtaek BAE, Suwon-si (KR); Jungim CHOE, Suwon-si (KR)

(21) Appl. No.: 18/237,168

(22) Filed: Aug. 23, 2023

(30) Foreign Application Priority Data
Nov. 17, 2022 (KR) 10-2022-0154926

(51) Int. Cl. H01L 27/146

(52) U.S. Cl. CPC H01L 27/1463; H01L 27/14632

(57) ABSTRACT

An image sensor comprising a substrate including a plurality of unit pixels and including a first surface facing a first direction and a second surface facing a second direction opposite to the first direction, and a pixel isolation structure passing through the substrate in the second direction between the unit pixels, wherein the pixel isolation structure includes a buried conductive pattern extending from the second surface of the substrate into an inside of the substrate, and an insulating structure covering a lower surface of the buried conductive pattern and extending between the substrate and the buried conductive pattern, a first level and a second level that is under the first level being defined, the lower surface of the buried conductive pattern being positioned at the second level.

### CROSS-REFERENCE TO RELATED APPLICATIONS

Korean Patent Application No. 10-2022-0154926, filed on Nov. 17, 2022, in the Korean Intellectual Property Office, is hereby incorporated by reference in its entirety.

### BACKGROUND

### 1. Field

An image sensor is disclosed.

### 2. Description of the Related Art

In semiconductor devices, an image sensor is a device to convert an optical image into an electric signal.

### SUMMARY

Embodiments are directed to an image sensor including a substrate including a plurality of unit pixels and including a first surface facing a first direction and a second surface facing a second direction opposite to the first direction, and a pixel isolation structure passing through the substrate in the second direction between the unit pixels, wherein the pixel isolation structure includes a buried conductive pattern extending from the second surface of the substrate into an inside of the substrate, and an insulating structure covering a lower surface of the buried conductive pattern and extending between the substrate and the buried conductive pattern, a first level and a second level that is under the first level being defined, the lower surface of the buried conductive pattern being positioned at the second level, and a width of the insulating structure in a third direction parallel to the second surface of the substrate at the first level being smaller than that at the second level.

Embodiments are directed to an image sensor including a substrate including a plurality of unit pixels and including a first surface facing a first direction and a second surface facing a second direction opposite to the first direction, and a pixel isolation structure passing through the substrate in the second direction between the unit pixels, wherein the pixel isolation structure includes a buried conductive pattern extending from the second surface of the substrate into an inside of the substrate, and an insulating structure covering a lower surface of the buried conductive pattern and extending between the substrate and the buried conductive pattern, the buried conductive pattern including a first conductive portion and a second conductive portion under the first conductive portion, and a width of the insulating structure in a third direction parallel to the second surface of the substrate being uniform on a side surface of the first conductive portion and increasing on a side surface of the second conductive portion toward the first direction.

Embodiments are directed to an image sensor including a substrate including first to fourth pixels sequentially disposed in a clockwise direction, and including a first surface facing a first direction and a second surface facing a second direction opposite to the first direction, and a pixel isolation structure passing through the substrate in the second direction between the first to fourth pixels, wherein the pixel isolation structure includes conductive liners extending from the second surface of the substrate into the substrate and surrounding each of the first to fourth pixels, and an insulating structure including a side portion extending between the substrate and each of the conductive liners, a first level and a second level that is under the first lever being defined, a lower end of each of the conductive liners being located at the second level, and a width of the side portion of the insulating structure in a third direction parallel to the second surface of the substrate at the first level being smaller than that at the second level.

### BRIEF DESCRIPTION OF THE DRAWINGS

Features will become apparent to those of skill in the art by describing in detail exemplary embodiments with reference to the attached drawings in which:

FIG. 1 is a block diagram of an image sensor according to example embodiments.

FIG. 2 is a circuit diagram of an active pixel sensor array of an image sensor according to example embodiments.

FIG. 3 is a plan view of an image sensor according to example embodiments.

FIGS. 4A and 4B are views of an image sensor according to example embodiments, and are cross-sectional views corresponding to lines A-A′ and B-B′ of FIG. 3, respectively.

FIGS. 5A to 6B are enlarged views corresponding to ‘P1’ of FIG. 4A.

FIGS. 7 to 14 are cross-sectional views of a method of manufacturing an image sensor according to example embodiments.

FIG. 15 is a plan view of an image sensor according to example embodiments.

FIGS. 16A and 16B are views of an image sensor according to example embodiments, and are cross-sectional views corresponding to lines C-C′ and D-D′ of FIG. 15, respectively.

FIG. 17 is a cross-sectional view of a method of manufacturing an image sensor according to example embodiments.

FIG. 18 is a plan view of an image sensor according to example embodiments.

FIGS. 19A and 19B are views of an image sensor according to example embodiments, and are cross-sectional views corresponding to E-E′ and F-F′ of FIG. 18, respectively.

FIGS. 20A to 20D are cross-sectional views corresponding to P4′ of FIG. 19A.

FIGS. 21A to 22B are cross-sectional views of a method of manufacturing an image sensor according to example embodiments.

FIG. 23 is a plan view of an image sensor according to example embodiments.

FIGS. 24A and 24B are views of an image sensor according to example embodiments, and are cross-sectional views corresponding to lines G-G′ and H-H′ of FIG. 23, respectively.

FIG. 25 is a cross-sectional view corresponding to P5′ in FIG. 24A.

FIGS. 26 and 27 are cross-sectional views of a method of manufacturing an image sensor according to example embodiments.

FIG. 28 is a plan view of an image sensor according to example embodiments.

FIG. 29 is a cross-sectional view of an image sensor according to example embodiments.

FIG. 30 is a cross-sectional view of an image sensor according to example embodiments.

### DETAILED DESCRIPTION

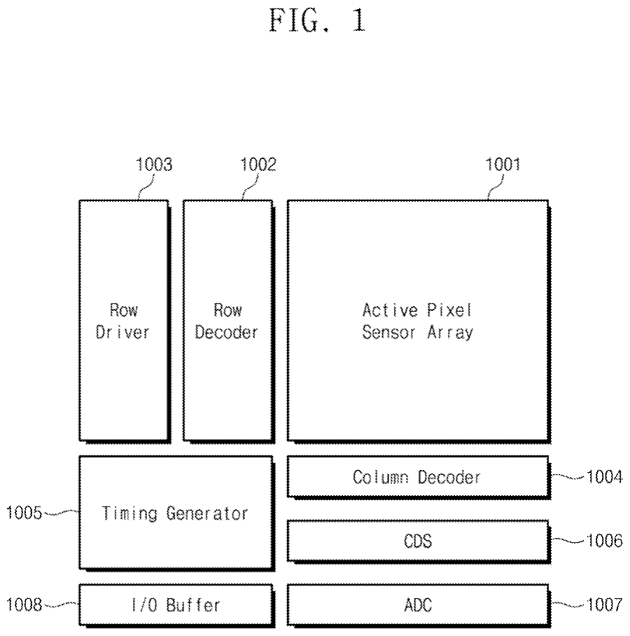

FIG. 1 is a block diagram of an image sensor according to example embodiments. Referring to FIG. 1, an image sensor may include an active pixel sensor array 1001, a row decoder 1002, a row driver 1003, a column decoder 1004, a timing generator 1005, a correlated double sampler (CDS) 1006, an analog-to-digital converter (ADC) 1007, and an input/output buffer (I/O buffer) 1008.

The active pixel sensor array 1001 may include a plurality of unit pixels, which may be two-dimensionally arranged, and may be configured to convert an optical signal to an electrical signal. The active pixel sensor array 1001 may be driven by a plurality of driving signals, such as a pixel selection signal, a reset signal, and a charge transfer signal, which may be transmitted from the row driver 1003. In addition, the converted electrical signal may be provided to the correlated double sampler 1006.

The row driver 1003 may be configured to provide a plurality of driving signals for driving the unit pixels of the active pixel sensor array 1001, based on the result decoded by the row decoder 1002. In the case where the unit pixels are arranged in rows and columns, the driving signals may be provided to respective rows.

The timing generator 1005 may be configured to provide a timing signal and a control signal to the row decoder 1002 and the column decoder 1004. The correlated double sampler 1006 may be configured to receive the electric signals generated by the active pixel sensor array 1001 and to perform a holding and sampling operation on the received electric signals. The correlated double sampler 1006 may perform a double sampling operation using a specific noise level and a signal level of the electric signal and then may output a difference level corresponding to a difference between the noise and signal levels.

The analog-to-digital converter 1007 may be configured to convert an analog signal, which may contain information on the difference level outputted from the correlated double sampler 1006, to a digital signal and to output the converted digital signal. The I/O buffer 1008 may be configured to latch the digital signals and then to sequentially output the latched digital signals to an image signal processing unit, based on the result decoded by the column decoder 1004.

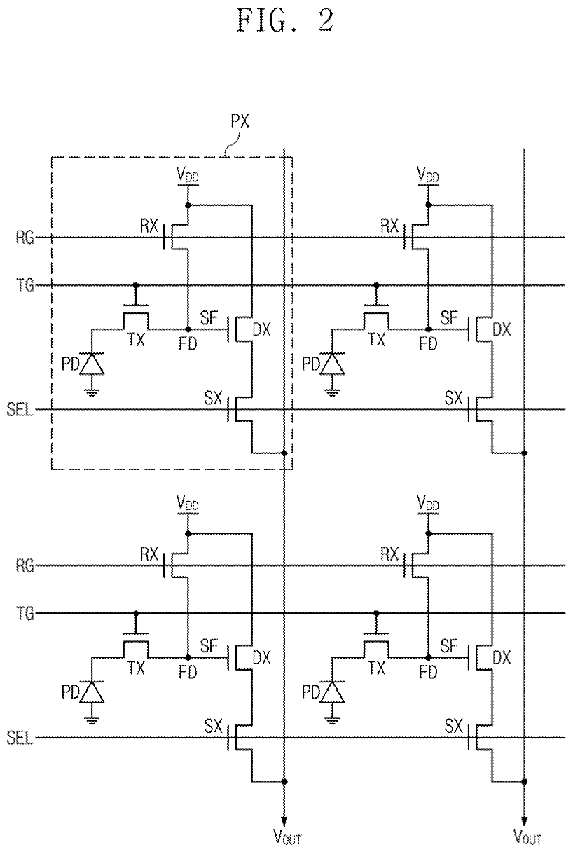

FIG. 2 is a circuit diagram of an active pixel sensor array of an image sensor according to example embodiments. Referring to FIGS. 1 and 2, the sensor array 1001 may include a plurality of unit pixels PX, which may be arranged in a matrix shape. Each of the unit pixels PX may include a transfer transistor TX. Each of the unit pixels may further include logic transistors RX, SX, and DX. The logic transistors may include a reset transistor RX, a selection transistor SX, and a source follower transistor DX. The transfer transistor TX may include a transfer gate TG. Each of the unit pixels PX may further include a photoelectric converter PD and a floating diffusion region FD. The logic transistors RX, SX, and DX may be shared by a plurality of unit pixels PX.

The photoelectric converter PD may be configured to generate photocharges whose amount may be proportional to an amount of externally incident light and to store the photocharges. The photoelectric converter PD may include a photo diode, a photo transistor, a photo gate, or a pinned photo diode. The transfer transistor TX may be configured to transfer electric charges, which may be generated in the photoelectric converter PD, to the floating diffusion region FD. The floating diffusion region FD may be configured to receive and cumulatively store the electric charges, which may be generated in the photoelectric converter PD. The source follower transistor DX may be controlled, based on an amount of photocharges stored in the floating diffusion region FD. As used herein, the term “or” is not an exclusive term, e.g., “A or B” would include A, B, or A and B.

The reset transistor RX may be configured to periodically discharge or reset the photocharges stored in the floating diffusion region FD. The reset transistor RX may include drain and source electrodes, which may be connected to the floating diffusion region FD and a power voltage VDD, respectively. When the reset transistor RX is turned on, the power voltage VDD connected to the source electrode of the reset transistor RX may be applied to the floating diffusion region FD. Thus, when the reset transistor RX is turned on, the electric charges stored in the floating diffusion region FD may be discharged, that is, the floating diffusion region FD may be reset.

The source follower transistor DX including a source follower gate electrode SF may serve as a source follower buffer amplifier. The source follower transistor DX may be configured to amplify a variation in electric potential of the floating diffusion region FD and to output the amplified signal to an output line Vout.

The selection transistor SX including a selection gate electrode SEL may select one of the rows of the unit pixels PX, during reading operations. When the selection transistor SX is turned on, the power voltage VDD may be applied to a drain electrode of the source follower transistor DX.

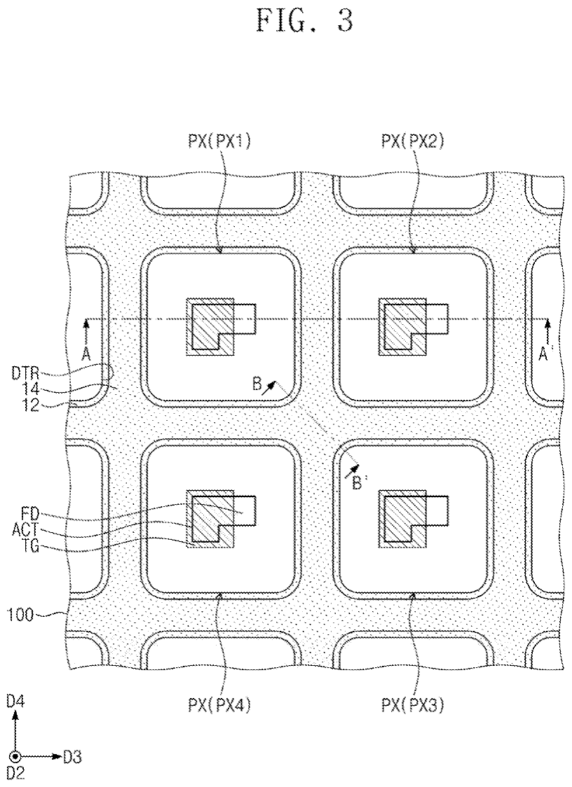

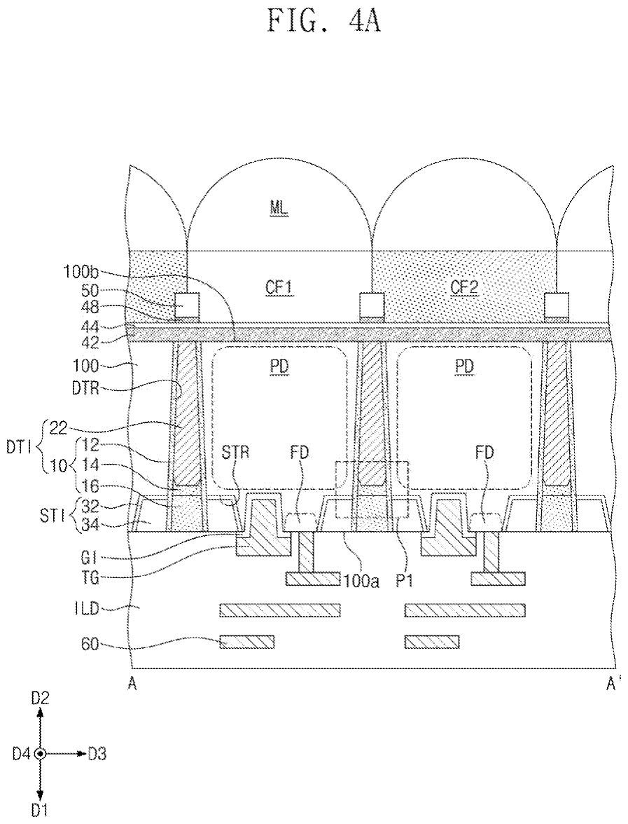

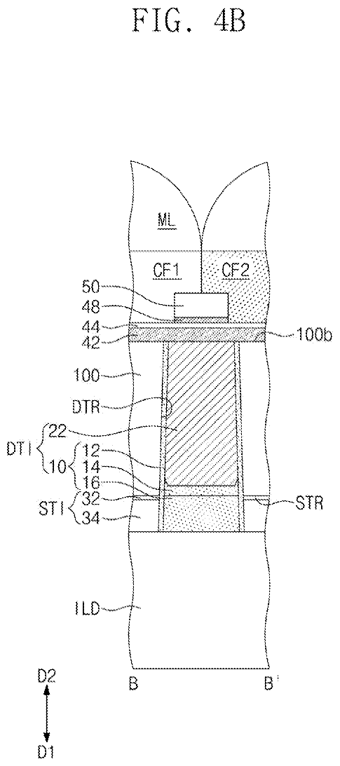

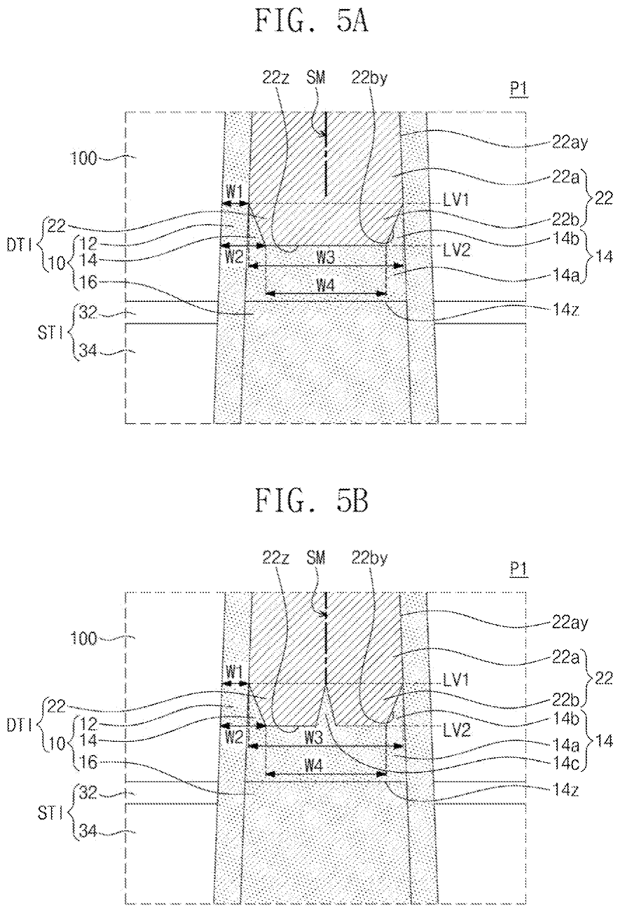

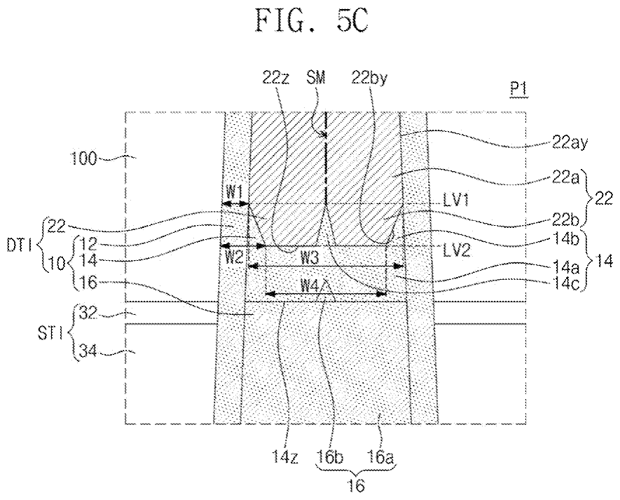

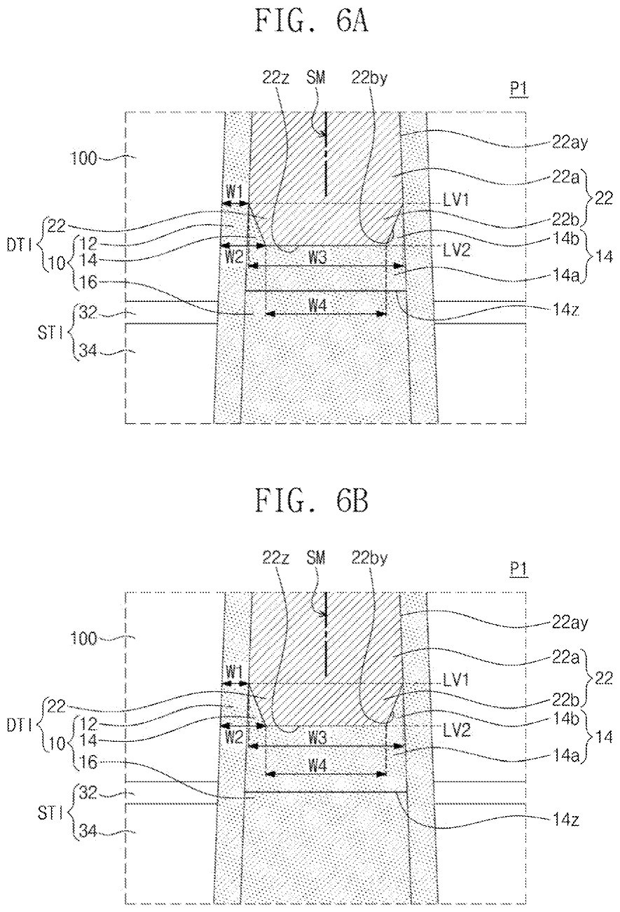

FIG. 3 is a plan view of an image sensor according to example embodiments. FIGS. 4A and 4B are views of an image sensor and are cross-sectional views corresponding to lines A-A′ and B-B′ of FIG. 3, respectively. FIGS. 5A to 6B are enlarged views corresponding to ‘P1’ of FIG. 4A.

Referring to FIGS. 3, 4A, and 4B, a substrate 100 may be provided. The substrate 100 may be, e.g., a silicon single crystal wafer, a silicon epitaxial layer, or a silicon on insulator (SOI) substrate. In an implementation, the substrate 100 may be doped with impurities having a first conductivity type (e.g., P type). The substrate 100 may include a first surface 100a and a second surface 100b that may be opposite to each other. The first surface 100a may face a first direction D1, and the second surface 100b may face a second direction D2. The first direction D1 and the second direction D2 may be opposite to each other.

The substrate 100 may include a plurality of unit pixels PX. In an implementation, when viewed from a plan view, the substrate 100 may include first, second, third, and fourth pixels PX1, PX2, PX3, and PX4 sequentially arranged in a clockwise direction. The first and second pixels PX1 and PX2 may be arranged side by side in a third direction D3, and the third and fourth pixels PX3 and PX4 may be also arranged side by side in the third direction D3. The third direction D3 may be a direction parallel to the second surface 100b of the substrate 100. The second and third pixels PX2 and PX3 may be arranged side by side in a fourth direction D4, and the first and fourth pixels PX1 and PX4 may be also arranged side by side in the fourth direction D4. The fourth direction D4 may be parallel to the second surface 100b of the substrate 100 and cross the third direction D3.

A pixel isolation structure DTI may be located in the substrate 100. The pixel isolation structure DTI may separate and define the unit pixels PX. The pixel isolation structure DTI may pass through the substrate 100 in the second direction D2 between the unit pixels PX. The pixel isolation structure DTI may be in a deep trench DTR extending from the first surface 100a toward the second surface 100b inside the substrate 100. When viewed from a plan view, the pixel isolation structure DTI may have a mesh shape where lines extending in the third and fourth directions D3 and D4 intersect with each other.

The pixel isolation structure DTI may include a buried conductive pattern 22 and an insulating structure 10. The buried conductive pattern 22 may extend into the substrate 100 from the second surface 100b of the substrate 100. An upper surface of the buried conductive pattern 22 may be positioned at substantially the same level as the second surface 100b. Unless otherwise specified, “level” in this specification refers to a height from the first surface 100a of the substrate 100 as a reference. A lower surface 22z of the buried conductive pattern 22 may be positioned at a higher level than an upper surface of a device isolation structure STI, which will be described later.

The buried conductive pattern 22 may include polysilicon with or without impurities. In an implementation, the buried conductive pattern 22 may include impurities having a conductivity type. In an implementation, the impurities may include boron.

The insulating structure 10 may include an insulating liner 12 and capping insulating patterns 14 and 16. The insulating liner 12 may be between the substrate 100 and the buried conductive pattern 22. The capping insulating patterns 14 and 16 may cover the lower surface 22z of the buried conductive pattern 22. The insulating liner 12 may surround side surfaces of the capping insulating patterns 14 and 16 and the buried conductive pattern 22. In an implementation, the insulating liner 12 and the capping insulating patterns 14 and 16 may be connected to each other without an interface. As another example, the insulating liner 12 and the capping insulating patterns 14 and 16 may be separated from each other by an interface.

The insulating liner 12 may be on an inner wall of the deep trench DTR. In an implementation, the insulating liner 12 may extend along the inner wall of the deep trench DTR between the substrate 100 and the buried conductive pattern 22. The insulating liner 12 may conformally cover the inner wall of the deep trench DTR. The insulating liner 12 may extend from the first surface 100a to the second surface 100b of the substrate 100. An upper surface of the insulating liner 12 may be positioned at substantially the same level as the buried conductive pattern 22 and the second surface 100b of the substrate 100 and may be coplanar with each other. When viewed from a plan view, the insulating liner 12 may surround each unit pixel PX.

The insulating liner 12 may include silicon oxide (SiO). In an implementation, the insulating liner 12 may further include a material other than silicon oxide e.g., silicon nitride (SiN), silicon carbonitride (SiCN), or silicon oxycarbonitride (SiOCN). The insulating liner 12 may be a single layer or a composite layer including two or more layers.

The capping insulating patterns 14 and 16 may include a first capping insulating pattern 14 and a second capping insulating pattern 16. The first capping insulating pattern 14 may be on the lower surface 22z of the buried conductive pattern 22. The second capping insulating pattern 16 may be on a lower surface 14z of the first capping insulating pattern 14. The first capping insulating pattern 14 may be between the buried conductive pattern 22 and the second capping insulating pattern 16.

An uppermost end of the first capping insulating pattern 14 may be positioned at a level higher than that of the lower surface 22z of the buried conductive pattern 22. A lower surface of the second capping insulating pattern 16 may be positioned at substantially the same level as that of the first surface 100a of the substrate 100 and a lower surface of the device isolation structure STI, which will be described later, and may be coplanar with each other.

The capping insulating patterns 14 and 16 may include silicon oxide. In an implementation, each of the first capping insulating pattern 14 and the second capping insulating pattern 16 may include silicon oxide. The capping insulating patterns 14 and 16 may include at least some of the same elements as elements constituting the buried conductive pattern 22. In an implementation, the first capping insulating pattern 14 may include the same element as at least some of the elements constituting the buried conductive pattern 22. In an implementation, the buried conductive pattern 22 may include silicon, and the first capping insulating pattern 14 may include silicon oxide. As another example, the second capping insulating pattern 16 may further include silicon nitride (SiN), silicon carbonitride (SiCN), or silicon oxycarbonitride (SiOCN).

Hereinafter, characteristics and embodiments of the buried conductive pattern 22 and the insulating structure 10 will be described in detail with reference to FIGS. 5A to 6B. Referring to FIGS. 5A to 6B, a portion (e.g., an upper portion) of the buried conductive pattern 22 may be defined as a first conductive portion 22a. In an implementation, the first conductive portion 22a may be a portion of the buried conductive pattern 22 in which a width of the buried conductive pattern 22 in the third direction D3 increases or is substantially uniform toward the first direction D1. Another portion (e.g., lower portion) of the buried conductive pattern 22 may be defined as a second conductive portion 22b. In an implementation, the second conductive portion 22b may be another portion of the buried conductive pattern 22 in which the width of the buried conductive pattern 22 in the third direction D3 decreases toward the first direction D1.

The insulating structure 10 may have a width in the third direction D3. A first level LV1 may be defined, and a width of the insulating structure 10 in the third direction D3 may be uniform at a level higher than the first level LV1. In an implementation, an interface between the first conductive portion 22a and the second conductive portion 22b may be located at the first level LV1. In an implementation, the width of the buried conductive pattern 22 in the third direction D3 may be maximum at the first level LV1. A level at which the lower surface 22z of the buried conductive pattern 22 (i.e., the lower surface of the second conductive portion 22b) is positioned may be defined as a second level LV2. As the first level LV1 approaches the second level LV2, the width of the buried conductive pattern 22 (i.e., the second conductive portion 22b) in the third direction D3 may increase.

The insulating liner 12 may be in contact with a side surface 22ay of the first conductive portion 22a. The insulating liner 12 may be spaced apart from a side surface 22by of the second conductive portion 22b. In an implementation, the insulating liner 12 may be spaced apart from the side surface 22by of the second conductive portion 22b by the first capping insulating pattern 14.

The first capping insulating pattern 14 may include a main portion 14a covering the lower surface 22z of the buried conductive pattern 22 and an outer protrusion 14b protruding from the second level LV2 to the first level LV1. The outer protrusion 14b may protrude from the lower surface 22z of the buried conductive pattern 22 in the second direction D2. The outer protrusion 14b may protrude between the buried conductive pattern 22 and the insulating liner 12. The outer protrusion 14b may separate the buried conductive pattern 22 and the insulating liner 12 from each other. The outer protrusion 14b may cover the side surface 22by of the second conductive portion 22b.

A width of the insulating liner 12 in the third direction D3 may be substantially uniform toward the first direction D1 from the side surface 22ay of the first conductive portion 22a and the side surface 22by of the second conductive portion 22b. In an implementation, the insulating structure 10 may have a first width W1 in the third direction D3 at the first level LV1, and the insulating liner 12 may have substantially the same width as the first width W1 at a level higher than the first level LV1. A width of the first capping insulating pattern 14 in the third direction D3 may decrease toward the first direction D1 from the side surface 22by of the second conductive portion 22b. As the width of the insulating structure 10 in the third direction D3 (i.e., from the first level LV1 to the second level LV2) on the side surface 22by of the second conductive portion 22b (i.e., between the first level LV1 and the second level LV2) may decrease toward the first direction D1. The insulating structure 10 may have a second width W2 in the third direction D3 at the second level LV2, and the first width W1 may be smaller than the second width W2.

A width of the second conductive portion 22b in the third direction D3 may be various depending on the level. In an implementation, the width of the second conductive portion 22b in the third direction D3 may decrease toward the first direction D1 (i.e., from the first level LV1 to the second level LV2). The second conductive portion 22b may have a third width W3 at the first level LV1 and may have a fourth width W4 at the second level LV2. The third width W3 may be greater than the fourth width W4.

The buried conductive pattern 22 may include a seam SM therein. The seam SM may extend substantially parallel to the first direction D1. A plurality of seams SM may be sequentially disposed in the first direction D1. In an implementation, the seam SM may be in the first conductive portion 22a. As another example, the seam SM may further extend toward the second conductive portion 22b.

Referring to FIGS. 5A to 5C, each of the first capping insulating pattern 14 and the second capping insulating pattern 16 may or may not include a protrusion.

Referring to FIG. 5A, the first capping insulating pattern 14 may include the outer protrusion 14b. The outer protrusion 14b may protrude between the buried conductive pattern 22 and the insulating liner 12. The first capping insulating pattern 14 may not include a protrusion protruding into the buried conductive pattern 22.

Referring to FIG. 5B, the first capping insulating pattern 14 may include an outer protrusion 14b and an inner protrusion 14c. The inner protrusion 14c may protrude toward the inside from the lower surface 22z of the buried conductive pattern 22. In an implementation, the inner protrusion 14c may extend in the second direction D2 from the inside of the second conductive portion 22b. As another example, the inner protrusion 14c may further extend into the first conductive portion 22a. In an implementation, the inner protrusion 14c may protrude to a level lower or higher than the first level LV1. Alternatively, as another example, the inner protrusion 14c may protrude up to the first level LV1. In an implementation, the inner protrusion 14c may be aligned with the seam SM inside the buried conductive pattern 22 in the first direction D1. A recessed region recessed from the lower surface 22z of the buried conductive pattern 22 in the second direction D2 may be provided. The inner protrusion 14c may fill the recessed region.

Referring to FIG. 5C, the second capping insulating pattern 16 may include a main portion 16a and a protrusion 16b. The main portion 16a of the second capping insulating pattern 16 may cover the lower surface 14z of the first capping insulating pattern 14. The protrusion 16b of the second capping insulating pattern 16 may protrude toward the inside from the lower surface 14z of the first capping insulating pattern 14. In an implementation, the protrusion 16b may extend in the second direction D2 inside the first capping insulating pattern 14. In an implementation, the protrusion 16b may be aligned with the inner protrusion 14c of the first capping insulating pattern 14 in the first direction D1. A recess region recessed from the lower surface 14z of the first capping insulating pattern 14 in the second direction D2 may be provided. The protrusion 16b may fill the recessed region.

Referring to FIGS. 5A, 6A, and 6B, the lower surface 14z of the first capping insulating pattern 14 may be positioned at various levels. In an implementation, as shown in FIG. 5A, the lower surface 14z of the first capping insulating pattern 14 may be positioned at substantially the same level as an upper surface of the device isolation structure STI, which will be described later. As another example, as shown in FIG. 6A, the lower surface 14z of the first capping insulating pattern 14 may be positioned at a higher level than the upper surface of the device isolation structure STI, which will be described later. As another example, as shown in FIG. 6B, the lower surface 14z of the first capping insulating pattern 14 may be positioned at a lower level than the upper surface of the device isolation structure STI, which will be described later.

Referring again to FIGS. 3, 4A and 4B, a photoelectric converter PD may be in each of the unit pixels PX. The photoelectric converter PD may be doped with impurities having a second conductivity type (e.g., N-type) opposite to the first conductivity type. The impurities doped in the photoelectric converter PD may form a PN junction with impurities having the first conductivity type in the substrate 100, and a photodiode may be provided therethrough.

A device isolation trench STR recessed into the substrate 100 from the first surface 100a of the substrate 100 may be provided, and the device isolation structure STI may fill a device isolation trench STR. Accordingly, the device isolation structure STI may be recessed into the substrate 100 from the first surface 100a. In an implementation, the device isolation structure STI may include a first isolation portion 32 and a second isolation portion 34. The first isolation portion 32 may conformally cover an inner wall of the device isolation trench STR. The second isolation portion 34 may fill an inside of the device isolation trench STR. The first and second isolation portions 32 and 34 may include silicon oxide (SiO), silicon nitride (SiN), silicon carbonitride (SiCN), or silicon oxycarbonitride (SiOCN). The silicon device isolation structure STI may be penetrated in the second direction D2 by the pixel isolation structure DTI. The device isolation structure STI may define active regions ACT adjacent to the first surface 100a of the substrate 100 in the unit pixel PX. The active regions ACT may be provided for the transistors TX, RX, DX, and SX of FIG. 2.

A transfer gate TG may be on the first surface 100a of the substrate 100 in each unit pixel PX. In an implementation, a portion of the transfer gate TG may be buried in the substrate 100. The transfer gate TG may be of a vertical type. As another example, the transfer gate TG may be a planar type on the first surface 100a of the substrate 100.

A gate insulating pattern GI may be between the transfer gate TG and the substrate 100. A floating diffusion region FD may be in the substrate 100 adjacent to one side of the transfer gate TG. In an implementation, an impurity having a second conductivity type may be doped into the floating diffusion region FD.

The image sensor may be a rear light receiving image sensor. In this case, light may be incident into the substrate 100 through the second surface 100b of the substrate 100. Electron-hole pairs may be generated at the PN junction by incident light. The electrons generated may move to the photoelectric converter PD. The electrons may move to the floating diffusion region FD as a voltage is applied to the transfer gate TG.

An interlayer insulating layer ILD may be on the first surface 100a of the substrate 100 and may cover the first surface 100a. The interlayer insulating layer ILD may be a composite layer including a silicon oxide layer, a silicon nitride layer, a silicon oxynitride layer, or a porous low-k dielectric layer. Wirings 60 may be in the interlayer insulating layer ILD. The floating diffusion region FD may be connected to the wirings 60.

A fixed charge layer 42 may be on the second surface 100b of the substrate 100 and may cover the second surface 100b. The fixed charge layer 42 may be a single layer or a composite layer including a metal oxide layer or a metal fluoride layer each containing oxygen or fluorine in an amount less than the stoichiometric ratio. As a result, the fixed charge layer 42 may have a negative fixed charge. In an implementation, the fixed charge layer 42 a metal oxide layer or a metal fluoride layer including hafnium (Hf), zirconium (Zr), aluminum (Al), tantalum (Ta), titanium (Ti), yttrium (Y), or a lanthanide. The fixed charge layer 42 may improve dark current and white spots.

A protective layer 44 may be stacked on the fixed charge layer 42. The protective layer 44 may include silicon oxide (SiO), silicon carbonate (SiOC), or silicon nitride (SiN). The protective layer 44 may function as an antireflective layer and/or a planarization layer.

Light blocking patterns 48 may be on the protective layer 44. Low refractive index patterns 50 may be respectively on the light blocking patterns 48. The light blocking pattern 48 and the low refractive index pattern 50 may overlap the pixel isolation structure DTI and may have a grid shape when viewed from a plan view. The light blocking pattern 48 may include titanium. The low refractive index patterns 50 may have the same thickness as each other and include the same organic material as each other. The low refractive index pattern 50 may have a lower refractive index than color filters CF1 and CF2 described later. In an implementation, the low refractive index pattern 50 may have a refractive index of about 1.3 or less. The light blocking pattern 48 and the low refractive index pattern 50 may prevent cross talk between adjacent unit pixels PX.

The color filters CF1 and CF2 may be between the low refractive index patterns 50. Each of the color filters CF1 and CF2 may have one color among blue, green, and red. As another example, the color filters CAF1 and CF2 may include other colors such as cyan, magenta, or yellow. In the image sensor according to the present embodiment, the color filters CF1 and CF2 may be arranged in a Bayer pattern. In another example, the color filters CF1 and CF2 may be arranged in a 2×2 tetra pattern, a 3×3 nona pattern, or a 4×4 hexadeca pattern.

Micro lenses ML may be on the color filters CF1 and CF2. Edges of the micro lenses ML may be in contact with each other and may be connected to each other.

The first capping insulating pattern 14 may be between the buried conductive pattern 22 and the second capping insulating pattern 16. The first capping insulating pattern 14 may be formed by oxidizing a portion of the buried conductive pattern 22, and the first capping insulating pattern 14 (i.e., the oxidized portion of the buried conductive pattern 22) may have a larger volume than the portion of the buried conductive pattern 22 before oxidation. The stress transmitted to the substrate 100 may be easily controlled through the change in volume, and as a result, warpage may be improved.

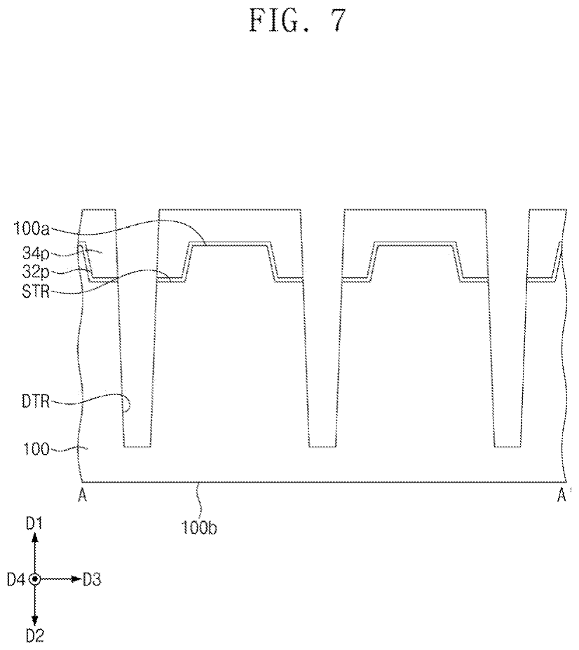

FIGS. 7 to 14 are cross-sectional views of a method of manufacturing an image sensor according to example embodiments. Hereinafter, A method of manufacturing an image sensor described with reference to FIGS. 3 to 6B will be described with reference to FIGS. 3 and 7 to 14. For simplicity of description, descriptions of overlapping contents with the foregoing contents will be omitted.

In the following description with reference to FIGS. 7 to 13, ‘upper surface’ and ‘lower surface’ respectively mean ‘lower surface’ and ‘upper surface’ in terms of a manufactured image sensor described with reference to FIGS. 3 to 6B, respectively. Similarly, in the description with reference to FIGS. 7 to 13, ‘upper’, ‘lower’, ‘above’ and ‘below’ mean ‘lower’, ‘upper’, ‘below’ and ‘above’ in terms of the manufactured image sensor described with reference to FIGS. 3 to 6B, respectively. Hereafter, even in the description with reference to FIGS. 17 and 21A to 22B, ‘upper surface’ may mean ‘lower surface’ as described above.

Referring to FIGS. 3 and 7, a substrate 100 may be prepared. A device isolation trench STR recessed into the substrate 100 from a first surface 100a of the substrate 100 may be formed. Forming the device isolation trench STR may include forming a mask pattern on the first surface 100a of the substrate 100 and etching the substrate 100 using the mask pattern as an etch mask. A portion of the mask pattern may or may not remain through the etching. The device isolation trench STR may define positions of active regions ACT on the substrate 100.

A first isolation layer 32p may cover an inner wall of the device isolation trench STR and the first surface 100a of the substrate 100. The first isolation layer 32p may include a mask pattern remaining after etching for forming the device isolation trench STR. A second isolation layer 34p may fill the remaining region of the device isolation trench STR and cover the first surface 100a of the substrate 100. Each of the first isolation layer 32p and the second isolation layer 34p may be silicon oxide (SiO), silicon nitride (SiN), silicon carbonitride (SiCN), or silicon oxycarbonitride (SiOCN).

A deep trench DTR may pass through the first isolation layer 32p, the second isolation layer 34p, and a portion of the substrate 100. When viewed from a plan view, the deep trench DTR may have a mesh shape in which lines extending in third and fourth directions D3 and D4 which may intersect each other. An inside of the substrate 100 may be exposed by the deep trench DTR. The deep trench DTR may define positions of unit pixels PX.

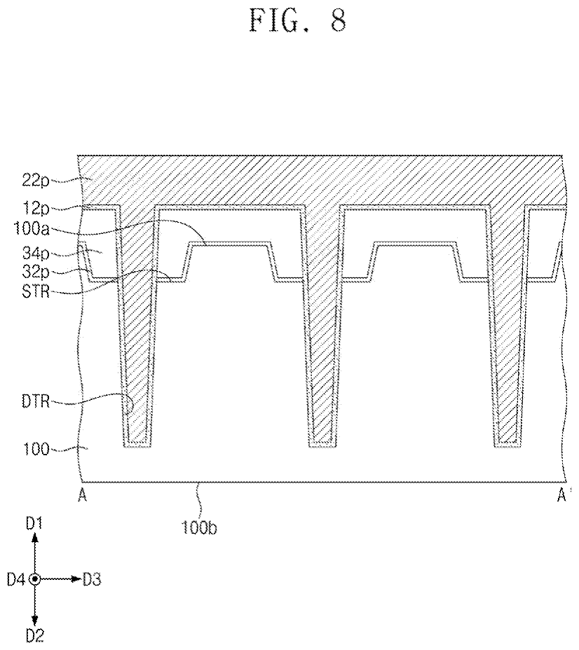

Referring to FIGS. 3 and 8, an insulating liner layer 12p may be on the first surface 100a of the substrate 100. The insulating liner layer 12p may conformally cover the first surface 100a of the substrate 100 and an inner wall of the deep trench DTR. The insulating liner layer 12p may fill a portion of the deep trench DTR. The insulating liner layer 12p may include silicon oxide (SiO). In an implementation, the insulating liner layer 12p may further include a material other than silicon oxide e.g., silicon nitride (SiN), silicon carbonitride (SiCN), or silicon oxycarbonitride (SiOCN). The insulating liner layer 12p may be a single layer or a composite layer including two or more layers.

A buried conductive layer 22p may be on the first surface 100a of the substrate 100. The buried conductive layer 22p may fill the deep trench DTR and cover the first surface 100a of the substrate. The buried conductive layer 22p may include polysilicon, e.g., amorphous polysilicon. During the process of forming the buried conductive layer 22p, a seam extending in a first direction D1 may be inside the buried conductive layer 22p.

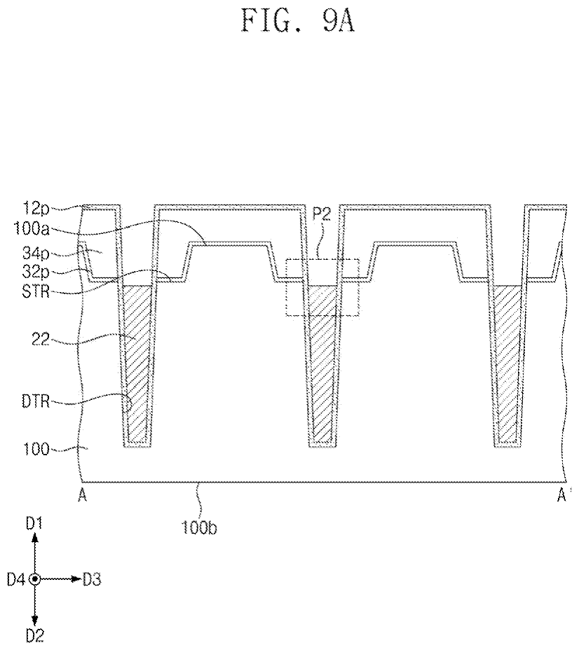

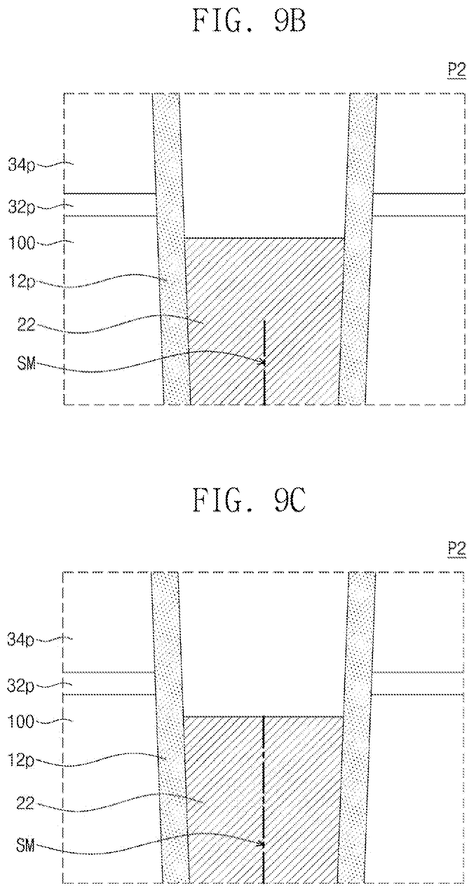

Referring to FIGS. 3 and 9A to 9C, an upper portion of the buried conductive layer 22p may be removed. Removing the upper portion of the buried conductive layer 22p may include performing an etch-back process on the buried conductive layer 22p. The buried conductive layer 22p remaining after the removal process may form the buried conductive pattern 22. The buried conductive pattern 22 may include seams SM therein. In an implementation, as shown in FIG. 9B, the seam SM may be located inside the buried conductive pattern 22 and may not be exposed to the outside. As another example, as shown in FIG. 9C, the seam SM may be exposed through an upper surface of the buried conductive pattern 22. The upper surface of the buried conductive pattern 22 may be at a level lower than that of the device isolation trench STR.

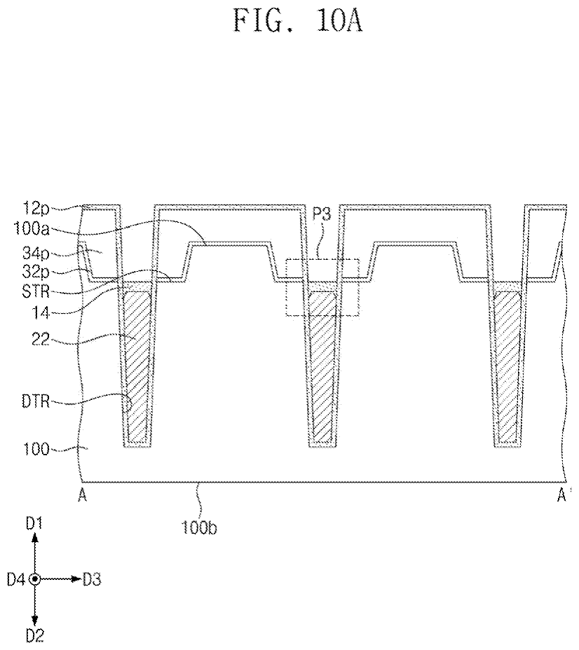

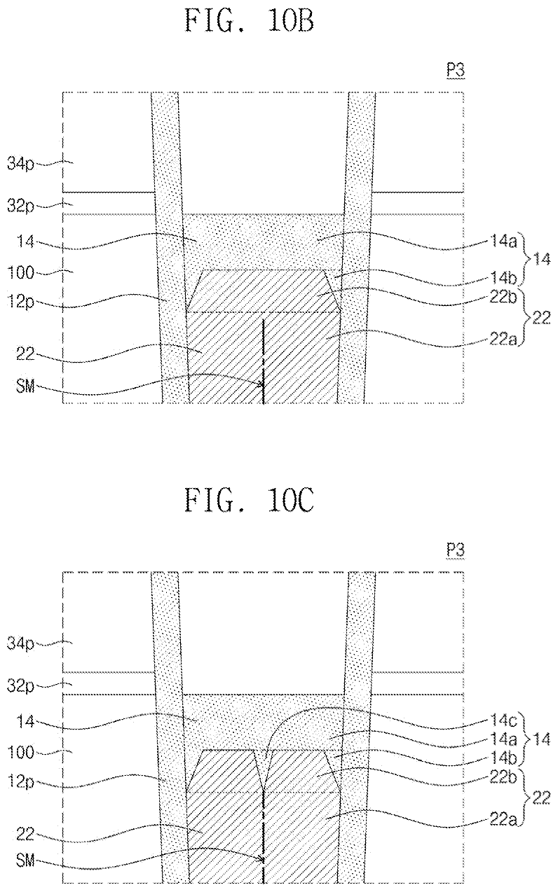

Referring to FIGS. 3 and 10A to 10C, a first capping insulating pattern 14 may be on the buried conductive pattern 22. Forming the first capping insulating pattern 14 may include oxidizing a portion of the buried conductive pattern 22 adjacent to the device isolation trench STR. Accordingly, the first capping insulating pattern 14 may include the same element as at least some of elements constituting the buried conductive pattern 22. In an implementation, the buried conductive pattern 22 may include silicon, and the first capping insulating pattern 14 may include silicon oxide.

A volume of the first capping insulating pattern 14 may be greater than a volume of the oxidized portion of the buried conductive pattern 22. Accordingly, an upper surface of the first capping insulating pattern 14 may be located at a higher level than the upper surface of the buried conductive pattern 22 in FIGS. 9A to 9C. The volume of the first capping insulating pattern 14 may be easily controlled by controlling the conditions of the oxidation process e.g., temperature or time. In an implementation, by performing the oxidation process for a long time in a high-temperature environment, the volume of the first capping insulating pattern 14 may increase. By controlling the volume of the first capping insulating pattern 14, compressive stress and tensile stress of the substrate 100 may be controlled. By controlling the stress, as a result, warpage that appears during the manufacturing process of the image sensor may be improved.

The oxidation process may proceed through various methods. According to some embodiments, the oxidation process may be a dry oxidation process, a wet oxidation process, a radical oxidation process, or a plasma oxidation process.

In an implementation, the dry oxidation process may include reacting the buried conductive pattern 22 with oxygen (O₂) gas at a high temperature (e.g., 700° C. or higher). As another example, a small amount of HCl may be further added during the dry oxidation process.

In an implementation, the wet oxidation process may include oxidizing the buried conductive pattern 22 by supplying oxygen and hydrogen. Oxygen and hydrogen may react to form water (H₂O), and the buried conductive pattern 22 may be oxidized by reacting with the water (H₂O).

In an implementation, the radical oxidation process may be performed by reacting oxygen and hydrogen to generate O radicals and/or OH radicals. In general, an oxidation rate may be various depending on a crystal direction of the buried conductive pattern 22, but the radical oxidation process may minimize a variation in the oxidation rate depending on the crystal direction of the buried conductive pattern 22.

In an implementation, the plasma oxidation process may be performed by oxidizing the buried conductive pattern 22 by generating oxygen plasma. The plasma oxidation process may be performed at a relatively low temperature compared to a dry oxidation process. Accordingly, during the manufacturing process of the image sensor, a change in characteristics of the image sensor due to heat may be minimized. The first capping insulating pattern 14 may include an outer protrusion 14b. The outer protrusion 14b may be between the insulating liner 12 and a side surface of the buried conductive pattern 22. During the oxidation process, oxidation may actively progress at a boundary of the buried conductive pattern 22 in contact with the insulating liner 12. Due to this, the oxidation may proceed to a deeper region of the buried conductive pattern 22 along the boundary between the insulating liner 12 and the buried conductive pattern 22. As a result, the outer protrusion 14b may be between the insulating liner 12 and the side surface of the buried conductive pattern 22.

In an implementation, as shown in FIG. 10B, the first capping insulating pattern 14 may not include an inner protrusion 14c. As described with reference to FIG. 9B, when forming the buried conductive pattern 22, the seam SM may not be exposed through the upper surface of the buried conductive pattern 22. In other words, the boundary surface due to the seam SM of the buried conductive pattern 22 may not be exposed. As a result, the first capping insulating pattern 14 may not include the inner protrusion 14c.

As another example, as shown in FIG. 10C, the first capping insulating pattern 14 may include an inner protrusion 14c. As described with reference to FIG. 9C, when the buried conductive pattern 22 is formed, the seam SM may be exposed to the outside. Accordingly, during the oxidation process, oxidation of the buried conductive pattern 22 may be easily performed along the boundary surface due to the seam SM of the buried conductive pattern 22. As a result, the first capping insulating pattern 14 may include the inner protrusion 14c. However, even when the seam SM is not exposed to the outside as shown in FIG. 9B, the oxidation may progress to the seam SM inside the buried conductive pattern 22 during the oxidation process. In this case, the inner protrusion 14c may be formed. An upper surface of the first capping insulating pattern 14 may be recessed along a profile of the inner protrusion 14c. In this case, the image sensor described with reference to FIG. 5C may be finally formed.

Referring to FIGS. 3 and 11, a capping insulating layer 16p may be on the first surface 100a of the substrate 100. The capping insulating layer 16p may cover the first surface 100a of the substrate 100 and fill the remaining portion of the deep trench DTR. According to some embodiments, an annealing process may be additionally performed after forming the capping insulating layer 16p.

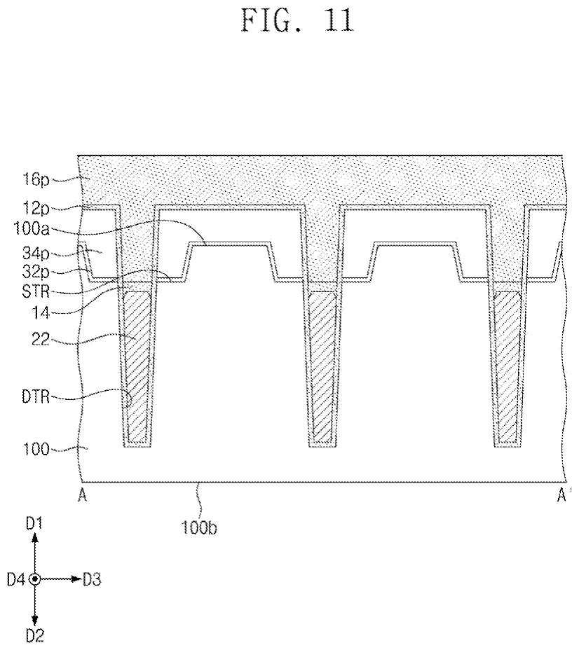

Referring to FIGS. 3 and 12, a planarization process may be performed. Performing the planarization process may include performing a chemical mechanical polishing (CMP) process. Through this, an upper portion of the insulating liner layer 12p, an upper portion of the capping insulating layer 16p, and an upper portion of the second isolation layer 34p may be removed, and thus an insulating liner 12, a second capping insulating pattern 16, and a second isolation portion 34 may be formed. In an implementation, a portion of the first isolation layer 32p may be exposed through the planarization process and may function as a polishing stop layer. The insulating liner 12, the first capping insulating pattern 14, and the second capping insulating pattern 16 may constitute an insulating structure 10. The insulating structure 10 and the buried conductive pattern 22 may form a pixel isolation structure DTI.

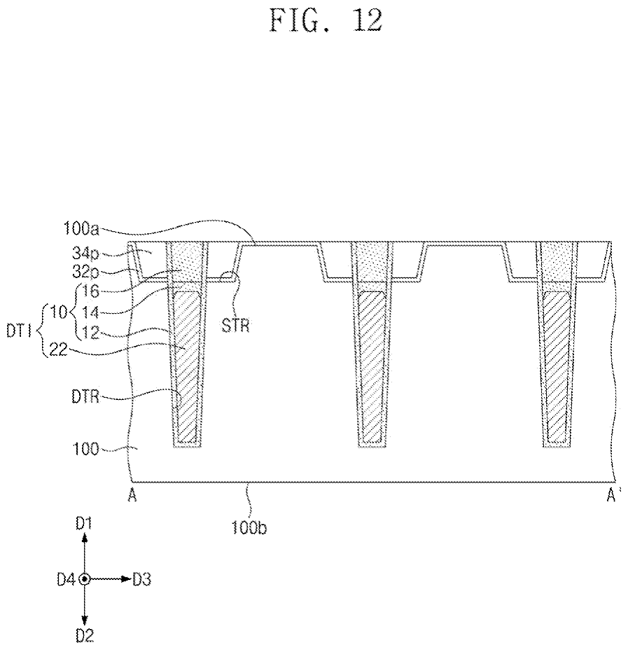

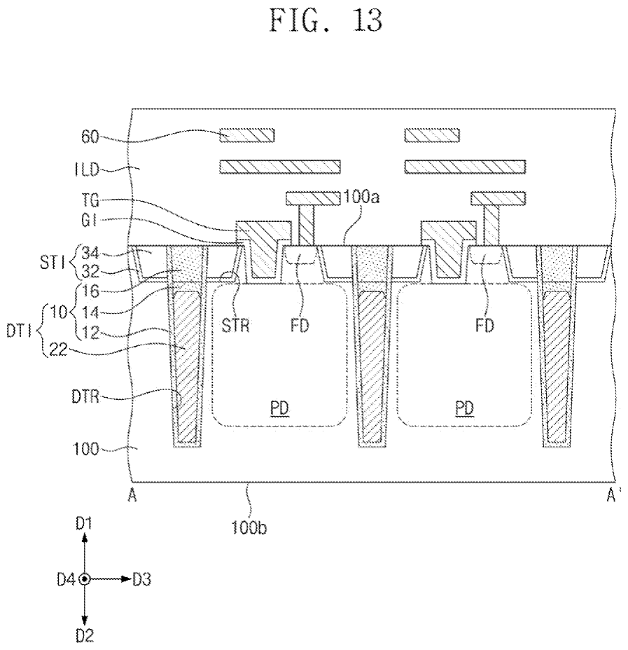

Referring to FIGS. 3 and 13, a portion of the first isolation layer 32p may be removed. The other portion of the first isolation layer 32p that is not removed may constitute the first isolation portion 32 in the device isolation trench STR and may constitute a device isolation structure STI together with the second isolation portion 34. According to some embodiments, an upper portion of the device isolation structure STI, an upper portion of the insulating liner 12, and an upper portion of the second capping insulating pattern 16 may be further removed. As a result, an upper surface of the element isolation structure STI, an upper surface of the insulating liner 12, and an upper surface of the second capping insulating pattern 16 may form a coplanar surface with the first surface 100a of the substrate.

As a portion of the first isolation layer 32p is removed, the first surface 100a of the substrate 100 may be exposed. An ion implantation process may be performed on the exposed first surface 100a, and thus the photoelectric converter PD may be formed therethrough. Thereafter, a transfer gate TG, a gate insulating pattern GI, and a floating diffusion region FD may be on the first surface 100a of the substrate 100. An interlayer insulating layer and wirings 60 may be on the first surface 100a of the substrate 100.

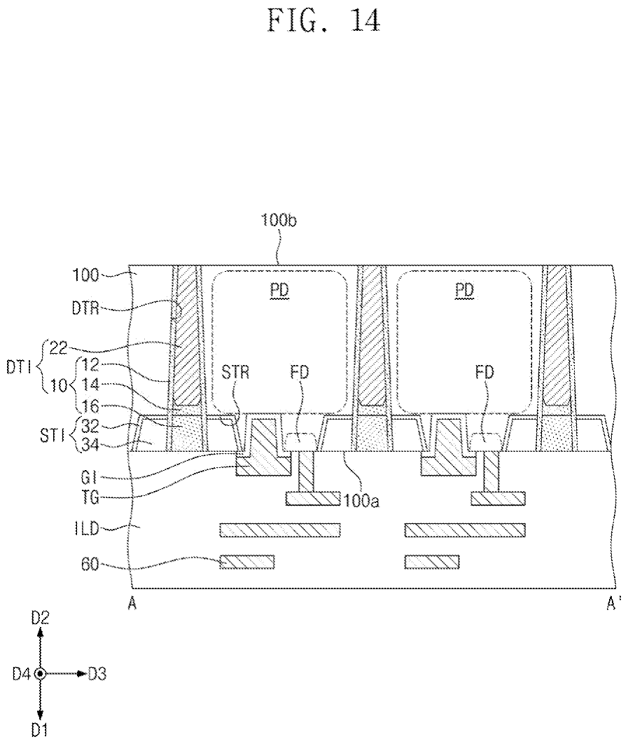

Referring to FIGS. 3 and 14, a back grinding process may be performed on a second surface 100b of the substrate 100. A portion of the substrate 100 and a portion of the pixel isolation structure DTI may be removed through the back grinding process. The insulating liner 12 and the buried conductive pattern 22 may be exposed through the back grinding process and may be substantially coplanar with the second surface 100b.

Referring again to FIGS. 3, 4A, and 4B, a fixed charge layer 42, a protective layer 44, a light blocking pattern 48, a low refractive index pattern 50, color filters CF1 and CF2, and micro lenses ML may be formed.

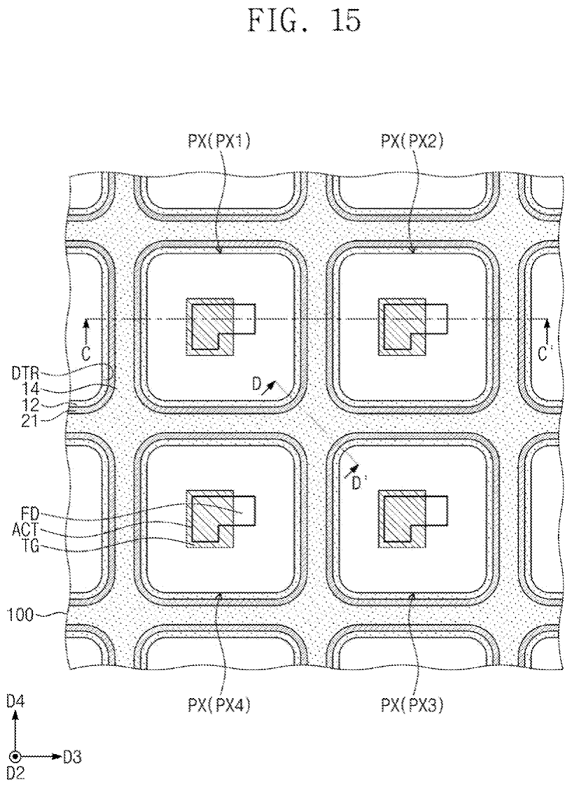

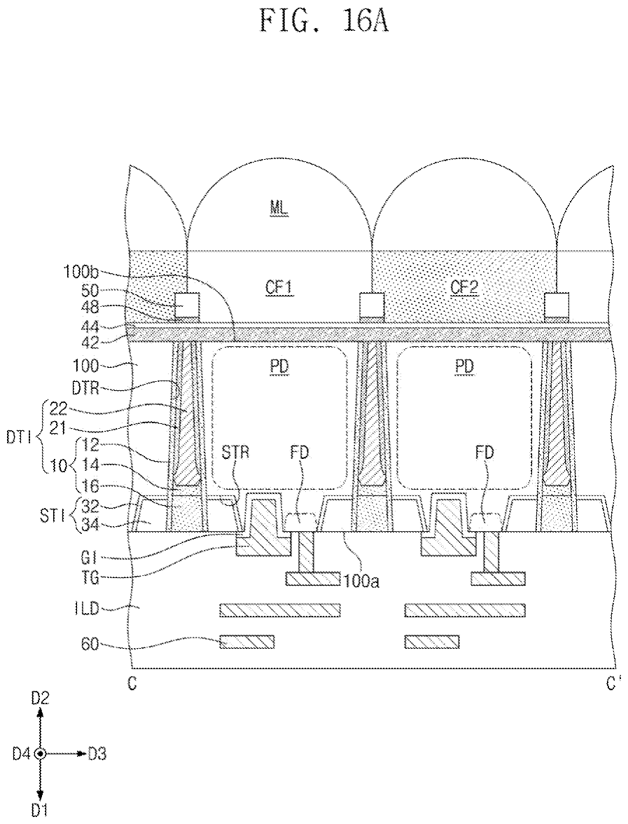

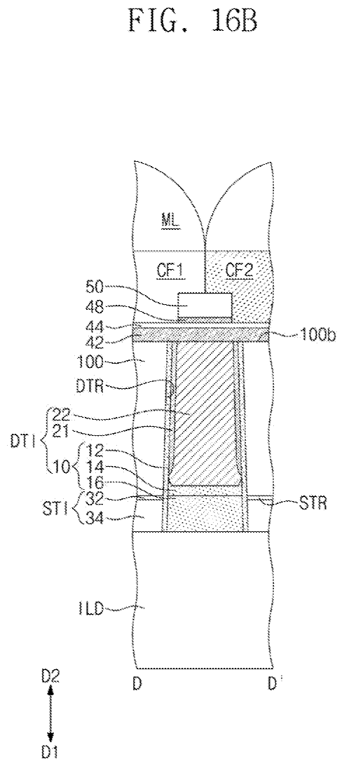

FIG. 15 is a plan view of an image sensor according to example embodiments. FIGS. 16A and 16B are views of an image sensor according to example embodiments, and are cross-sectional views corresponding to lines C-C′ and D-D′ of FIG. 15, respectively.

Referring to FIGS. 15, 16A and 16B, a conductive liner 21 may be inside a deep trench DTR. The conductive liner 21 may extend between a buried conductive pattern 22 and an insulating liner 12. The conductive liner 21 may cover at least a portion of a side surface of the buried conductive pattern 22. When viewed in a plan view, the conductive liner 21 may surround each unit pixel PX.

The conductive liner 21 may include the same element as at least some of elements constituting the buried conductive pattern 22. In an implementation, the conductive liner 21 and the buried conductive pattern 22 may include silicon. The conductive liner 21 and the buried conductive pattern 22 may include impurities having a conductivity type. In an implementation, the impurities may include boron. A concentration of the impurities of the conductive liner 21 may be higher than that of the buried conductive pattern 22. An average size of grains in the conductive liner 21 may be greater than an average size of grains in the buried conductive pattern 22.

FIG. 17 is a cross-sectional view of a method of manufacturing an image sensor according to example embodiments. Hereinafter, with reference to FIGS. 15 and 17, a manufacturing method of an image sensor described with reference to FIGS. 15 and 16 will be described. For simplicity of description, descriptions of overlapping contents with the foregoing contents will be omitted.

Referring to FIGS. 15 and 17, after forming the insulating liner layer 12p described with reference to FIG. 8, a conductive liner layer may be formed. The conductive liner layer may conformally cover the insulating liner layer 12p. The conductive liner layer may cover the inner wall of the deep trench DTR and the first surface 100a of the substrate 100. In forming the conductive liner layer, impurities (e.g., boron) may be doped in-situ.

The conductive liner 21 may be formed by removing an upper portion of the conductive liner layer. The remaining conductive liner layer that is not removed may constitute the conductive liner 21. Thereafter, the buried conductive layer 22p may be formed, and an image sensor may be formed using the manufacturing method described with reference to FIGS. 9A to 14.

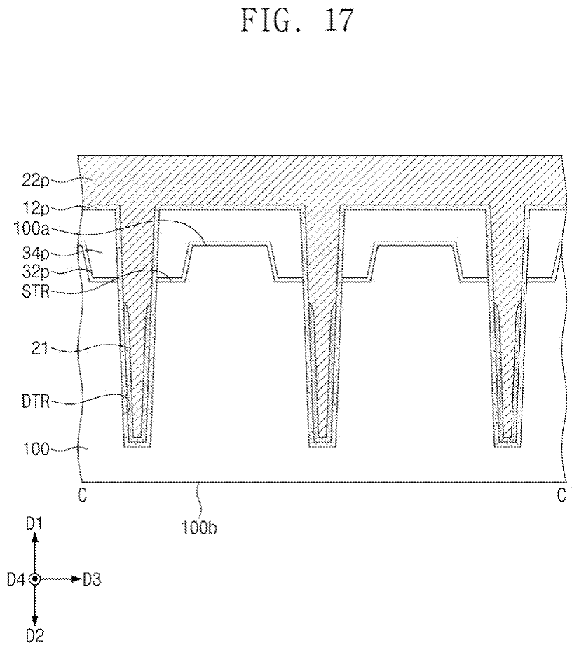

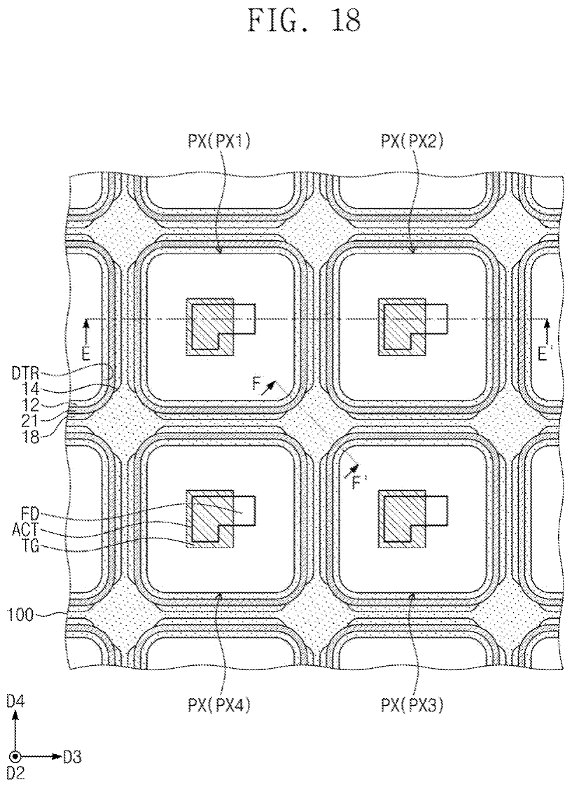

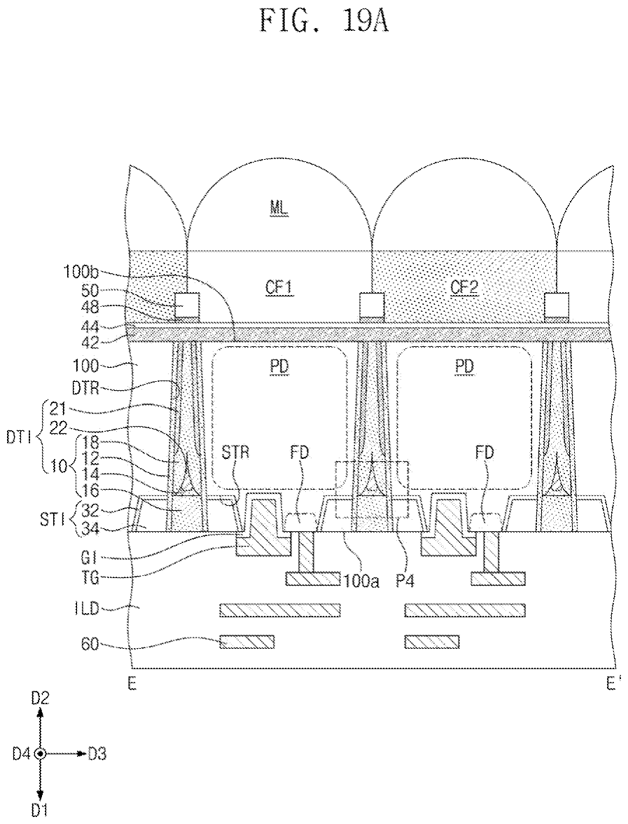

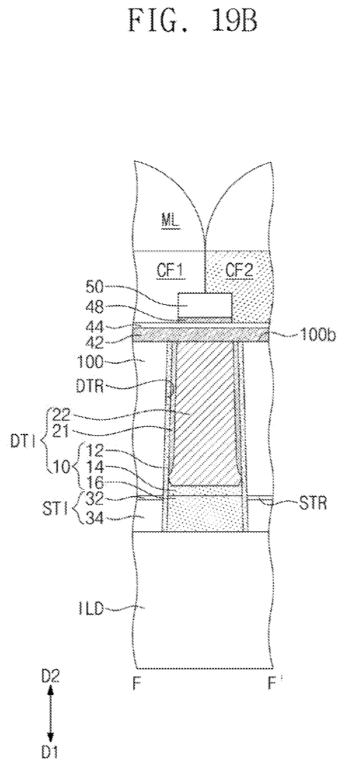

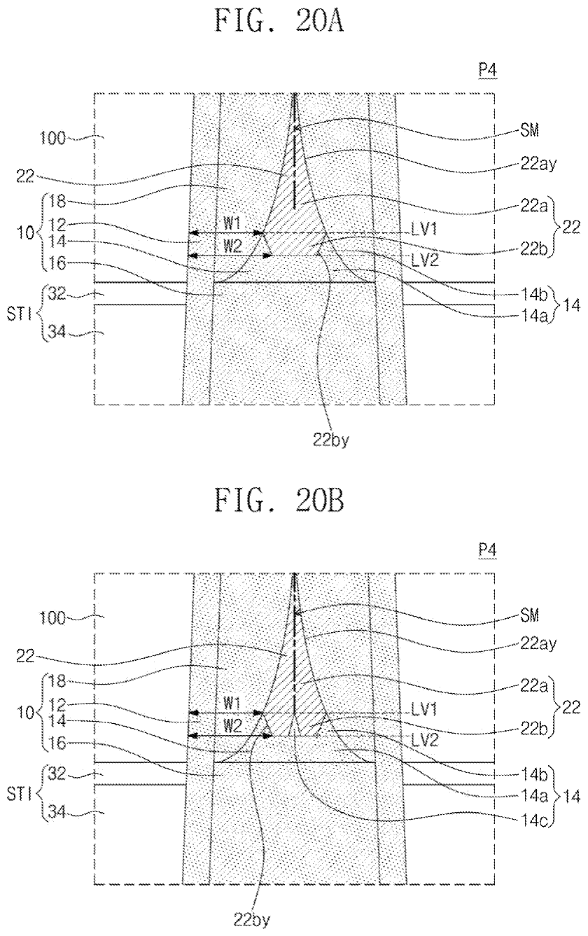

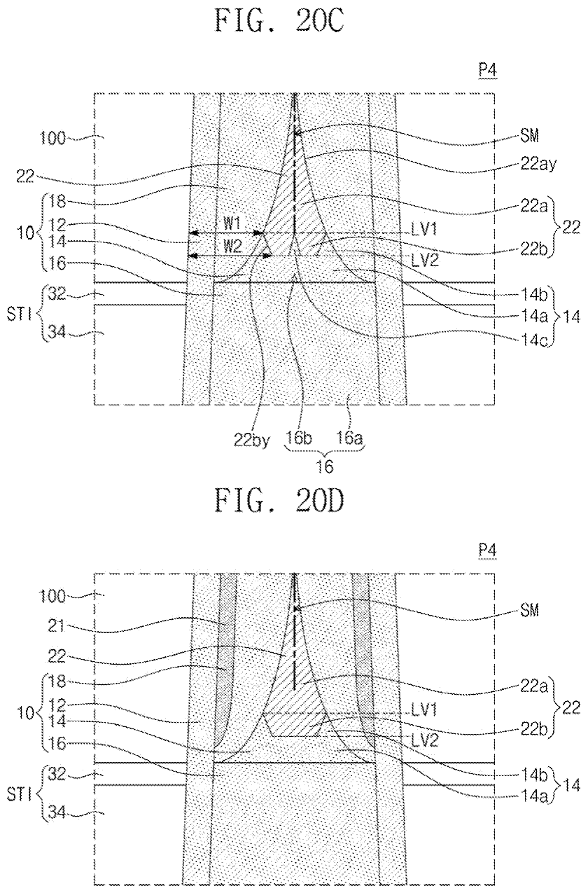

FIG. 18 is a plan view of an image sensor according to example embodiments. FIGS. 19A and 19B are views of an image sensor according to example embodiments and are cross-sectional views corresponding to E-E′ and F-F′ of FIG. 18, respectively. FIGS. 20A to 20D are cross-sectional views corresponding to ‘P4’ of FIG. 19A.

Referring to FIGS. 18, 19A and 19B, an insulating structure 10 may further include a buried insulating pattern 18. The buried insulating pattern 18 may be between the conductive liner 21 and the buried conductive pattern 22. The conductive liner 21 may be between the buried insulating pattern 18 and the insulating liner 12. A groove may be under the buried insulating pattern 18, and the buried conductive pattern 22 may fill the groove below the buried insulating pattern 18.

In an implementation, when viewed in a plan view, the buried insulating pattern 18 may cover the side of each unit pixel PX. The buried insulating pattern 18 may be between unit pixels PX adjacent to each other in the third direction D3 or the fourth direction D4. In an implementation, the buried insulating pattern 18 may be between a first pixel PX1 and a second pixel PX2, between the second pixel PX2 and a third pixel PX3, and between the third pixel PX3 and a fourth pixel PX4, and between the fourth pixel PX4 and the first pixel PX1. As another example, when viewed in a plan view, the buried insulating pattern 18 may not cover a corner of each unit pixel. In an implementation, the buried insulating pattern 18 may not be between the first pixel PX1 and the third pixel PX3 and between the second pixel PX2 and the fourth pixel PX4.

In an implementation, the buried insulating pattern 18 may be connected to the adjacent insulating liner 12 and the capping insulating patterns 14 and 16 without a boundary therebetween. As another example, the buried insulating pattern 18 may be separated from at least one of the insulating liner 12 and the capping insulating patterns 14 and 16 adjacent to each other by a boundary surface. The buried insulating pattern 18 may include silicon oxide (SiO), silicon nitride (SiN), silicon carbonitride (SiCN), silicon oxynitride (SiON), or silicon oxycarbonitride (SiOCN).

Referring to FIGS. 20A to 20C, the buried conductive pattern 22 may be buried inside the buried insulating pattern 18. The buried conductive pattern 22 may be between the buried insulating pattern 18 and the first capping insulating pattern 14. The buried conductive pattern 22 may include a first conductive portion 22a and a second conductive portion 22b. A width of the first conductive portion 22a in the third direction D3 may increase or be substantially uniform toward the first direction D1. A width of the second conductive portion 22b in the third direction D3 may decrease toward the first direction D1. The buried conductive pattern 22 may include a seam SM therein.

The side surface 22ay of the first conductive portion 22a may be in contact with the buried insulating pattern 18. The side surface 22by of the second conductive portion 22b may be spaced apart from the buried insulating pattern 18. In an implementation, the side surface 22by of the second conductive portion 22b may be spaced apart from the buried insulating pattern 18 by the first capping insulating pattern 14.

The first capping insulating pattern 14 may include a main portion 14a covering the lower surface 22z of the buried conductive pattern 22 and an outer protrusion 14b protruding between the buried conductive pattern 22 and the buried insulating pattern 18 (e.g., between the second conductive portion 22b and the buried insulating pattern 18). The outer protrusion 14b may cover the side surface 22by of the second conductive portion 22b.

The insulating structure 10 may have a first width W1 in the third direction D3 at the first level LV1 and a second width W2 in the third direction D3 at the second level LV2. The first width W1 may be smaller than the second width W2.

In an implementation, as shown in FIG. 20A, the first capping insulating pattern 14 may not include a protrusion protruding into the buried conductive pattern 22. As another example, as shown in FIG. 20B, the first capping insulating pattern 14 may include an inner protrusion 14c protruding toward the inside from the lower surface 22z of the buried conductive pattern 22. In this case, the second capping insulating pattern 16 may not include a protrusion protruding into the first capping insulating pattern 14. As another example, as shown in FIG. 20C, the second capping insulating pattern 16 may include a protrusion 16b protruding from the lower surface of the first capping insulating pattern 14 toward the inside thereof.

Referring to FIG. 20D, the conductive liner 21 may extend to an region adjacent to the device isolation structure STI. In an implementation, the conductive liner 21 may extend in the first direction D1 down to the second level LV2. The conductive liner 21 may extend in the first direction D1 up to a level higher than the second level LV2.

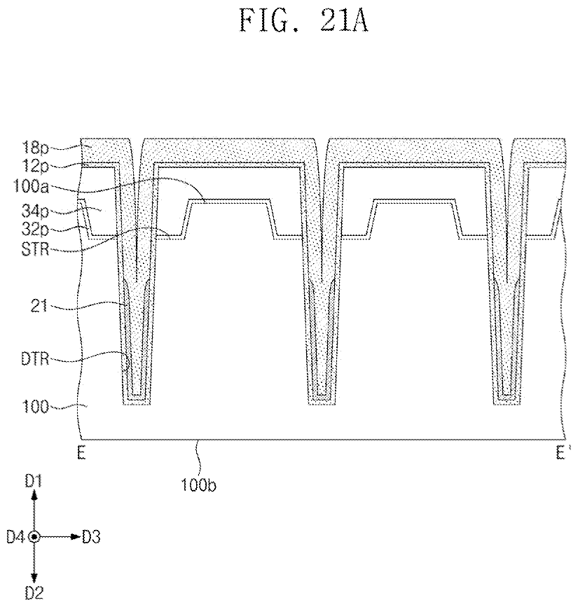

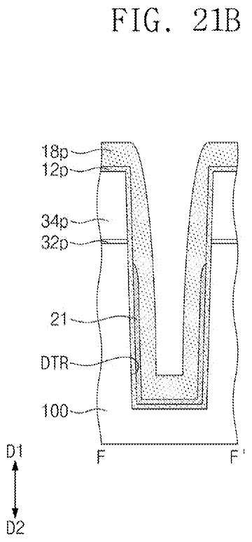

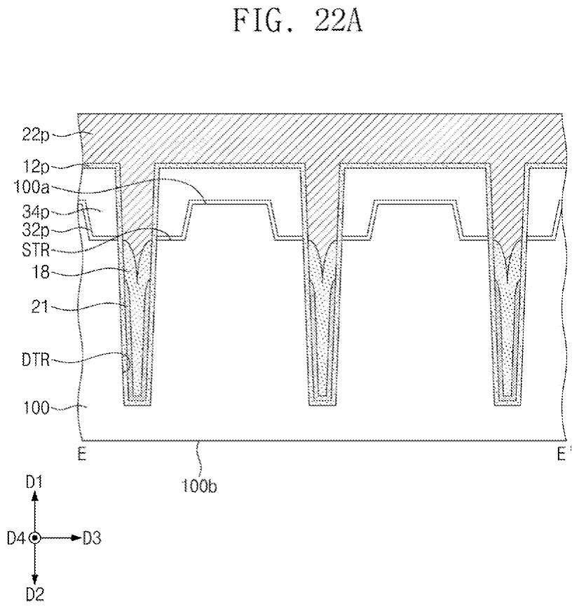

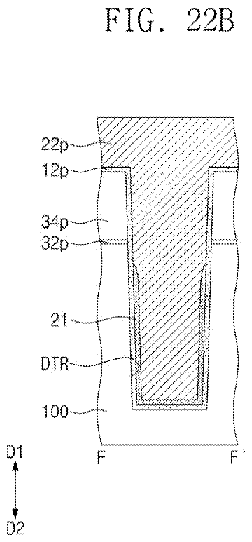

FIGS. 21A to 22B are cross-sectional views of a method of manufacturing an image sensor according to example embodiments. Hereinafter, a method of manufacturing an image sensor described with reference to FIGS. 18 to 20C will be described with reference to FIGS. 18 and 21A to 22B. For simplicity of description, descriptions of overlapping contents with the foregoing contents will be omitted.

Referring to FIGS. 18, 21A, and 21B, after forming the conductive liner 21 described with reference to FIG. 17, a buried insulating layer 18p may be formed. The buried insulating layer 18p may cover the inner wall of the deep trench DTR and the first surface 100a of the substrate 100. In an implementation, the buried insulating layer 18p may fill a lower portion of the deep trench DTR between unit pixels adjacent to each other in the third or fourth directions D3 and D4, and may conformally cover the inner wall of the upper portion of the deep trench DTR. As another example, the buried insulating layer 18p may conformally cover a corner of each unit pixel. An upper surface of the buried insulating layer 18p may have a groove following a profile of the deep trench DTR. The buried insulating layer 18p may include silicon oxide (SiO), silicon nitride (SiN), silicon carbonitride (SiCN), silicon oxynitride (SiON), or silicon oxycarbonitride (SiOCN).

Referring to FIGS. 18, 22A, and 22B, a removal process for the buried insulating layer 18p may be performed. The process of removing the buried insulating layer 18p may include an anisotropic etching process. In an implementation, between unit pixels adjacent to each other in the third or fourth directions D3 and D4, an upper portion of the buried insulating layer 18p may be removed. The remaining buried insulating layer 18p that is not removed may constitute the buried insulating pattern 18. As the buried insulating layer 18p has the groove, the buried insulating pattern 18 may also have a groove on an upper surface thereof. As another example, the conductive liner 21 may be exposed by removing the insulating liner 12 at the corner of each unit pixel. Thereafter, the buried conductive layer 22p may be formed, and an image sensor may be formed using the manufacturing method described with reference to FIGS. 9A to 14.

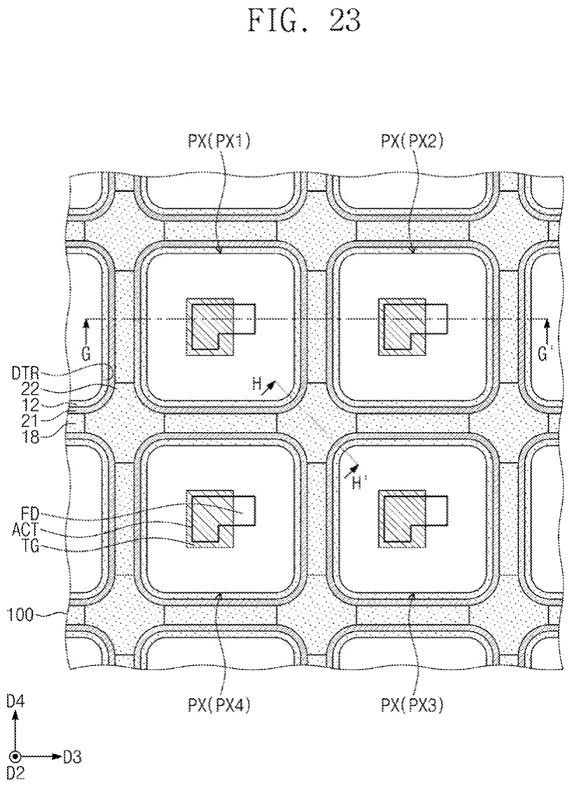

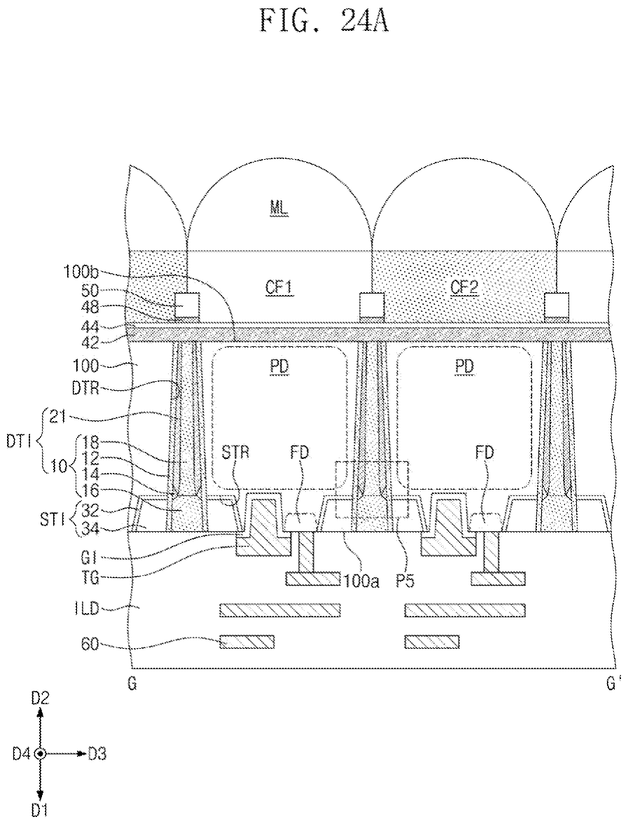

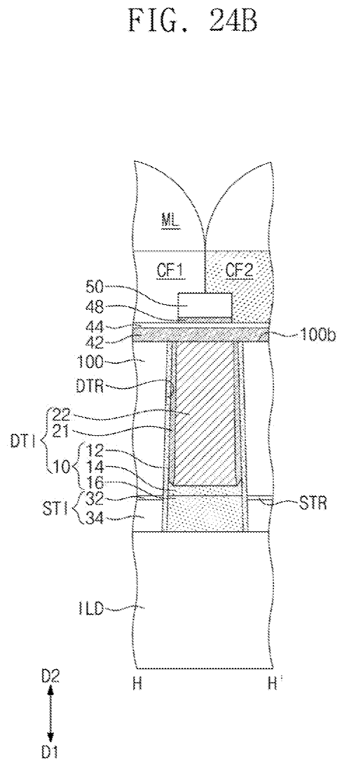

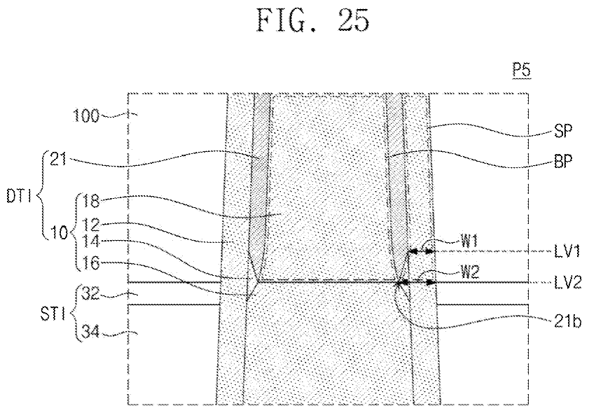

FIG. 23 is a plan view of an image sensor according to example embodiments. FIGS. 24A and 24B are views of an image sensor according to example embodiments and are cross-sectional views corresponding to lines G-G′ and H-H′ of FIG. 23, respectively. FIG. 25 is a cross-sectional view corresponding to ‘P5’ in FIG. 24A.

Referring to FIGS. 23, 24A, 24B, and 25, the buried conductive pattern 22 may be locally provided in the deep trench DTR. The buried conductive pattern 22 may not be between unit pixels PX adjacent to each other in the third direction D3 or the fourth direction D4. In an implementation, the buried conductive pattern 22 may not be between the first pixel PX1 and the second pixel PX2, between the second pixel PX2 and the third pixel PX3, and between the third pixel PX3 and the four pixels PX4, and between the fourth pixel PX4 and the first pixel PX1. As another example, the buried conductive pattern 22 may be between the first pixel PX1 and the third pixel PX3 and between the second pixel PX2 and the fourth pixel PX4. A plurality of buried conductive patterns 22 may be provided and may be spaced apart from each other in the third and fourth directions D3 and D4. When viewed in a cross-section view, the buried conductive pattern 22 may extend from the second surface 100b of the substrate 100 to the inside of the substrate 100.

The buried insulating pattern 18 may be between unit pixels PX adjacent to each other in the third direction D3 or the fourth direction D4. In an implementation, when viewed in a plan view, the buried insulating pattern 18 may cover the side of each unit pixel PX. The buried insulating pattern 18 may be between unit pixels PX adjacent to each other in the third direction D3 or the fourth direction D4. In an implementation, the buried insulating pattern 18 may be between the first pixel PX1 and the second pixel PX2, between the second pixel PX2 and the third pixel PX3, and between the third pixel PX3 and the fourth pixel PX4, and between the fourth pixel PX4 and the first pixel PX1. As another example, from a plan view, the buried insulating pattern 18 may not cover the corner of each unit pixel. In an implementation, the buried insulating pattern 18 may not be between the first pixel PX1 and the third pixel PX3 and between the second pixel PX2 and the fourth pixel PX4.

The conductive liner 21 may surround each of the unit pixels PX. The first capping insulating pattern 14 may be adjacent to the lower portion of the conductive liner 21 and the lower portion of the buried conductive pattern 22. In an implementation, the insulating liner 12, the first capping insulating pattern 14, the second capping insulating pattern 16, and the buried insulating pattern 18 may constitute the insulating structure 10 and may be connected to each other without a boundary. Accordingly, the conductive liner 21 may be surrounded by the insulating structure 10.

A portion of the insulating structure 10 may be between the substrate 100 and the conductive liner 21 at a level higher than the second level LV2, and the portion may be defined as a side portion SP. In an implementation, the side portion SP may include a portion of the insulating liner 12 and a portion of the first capping insulating pattern 14. A width of the side portion SP in the third direction D3 may be various depending on the level. The side portion SP may have a first width W1 at the first level LV1 and may have a second width W2 at the second level LV2. The first width W1 may be smaller than the second width W2. A width of the side portion SP in the third direction D3 may increase from the first level LV1 to the second level LV2. At a level higher than the first level LV1, the width of the side portion SP in the third direction D3 may be uniform.

Another portion of the insulating structure 10 may extend into the substrate 100 between the conductive liners 21, and the other portion may be defined as a buried portion BP. The buried portion BP may include at least a portion of the buried insulating pattern 18. The buried portion BP may be between unit pixels PX adjacent to each other in the third direction D3 or the fourth direction D4.

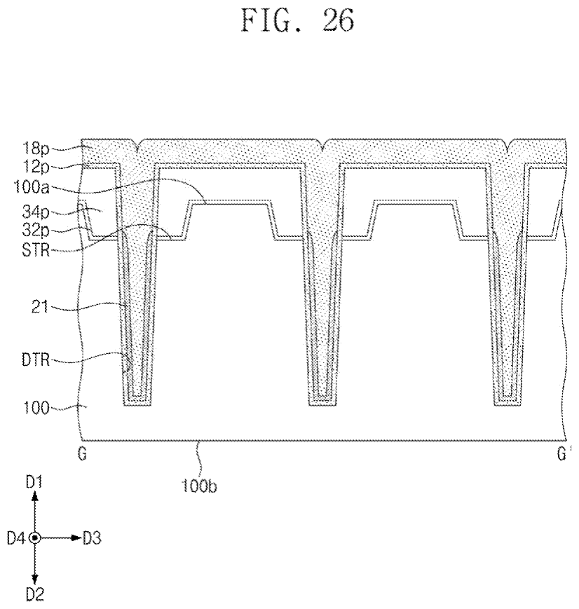

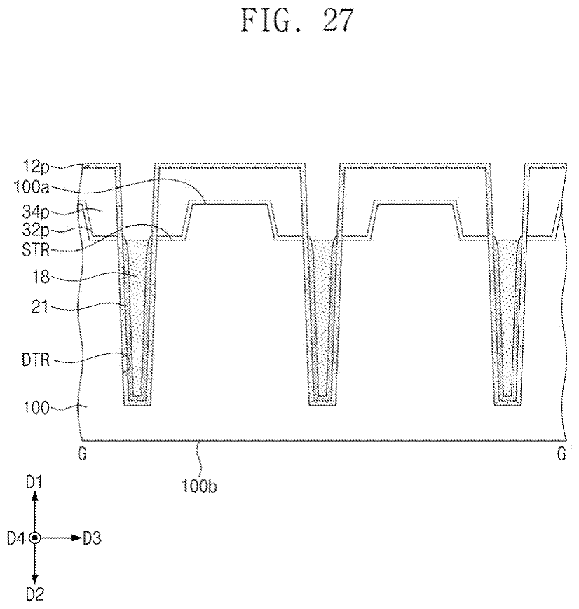

FIGS. 26 and 27 are cross-sectional views of a method of manufacturing an image sensor according to example embodiments. Hereinafter, a method of manufacturing an image sensor described with reference to FIGS. 23, 26, and 27, and FIGS. 24A, 25B, and 25 will be described. For simplicity of description, descriptions of overlapping contents with the foregoing contents will be omitted.

Referring to FIGS. 23 and 26, the conductive liner 21 described with reference to FIG. 17 may be formed. In an implementation, the conductive liner 21 may extend to a region adjacent to the device isolation trench STR. In an implementation, the conductive liner 21 may extend to a level higher than the lower surface of the device isolation trench STR. Then, as described with reference to FIG. 21A, a buried insulating layer 18p may be formed. In an implementation, as shown in FIG. 26, between unit pixels adjacent to each other in the third or fourth directions D3 and D4, the upper surface of the buried insulating layer 18p may have a groove along the profile of the deep trench DTR. However, the groove may be shallower than the groove of FIG. 21. The upper surface of the buried insulating layer 18p may be flat. The buried insulating layer 18p may be formed at the corner of each unit pixel and conformally cover the corner of each unit pixel as in FIG. 21B.

Referring to FIGS. 23 and 27, a removal process for the buried insulating layer 18p may be performed. The process of removing the buried insulating layer 18p may include an anisotropic etching process. In an implementation, between unit pixels adjacent to each other in the third or fourth directions D3 and D4, the upper portion of the buried insulating layer 18p may be removed. The remaining buried insulating layer 18p that is not removed may constitute the buried insulating pattern 18. The upper surface of the buried insulating pattern 18 may be flat. As another example, as shown in FIG. 22B, the conductive liner 21 may be exposed by removing the buried insulating layer 18p at the corner of each unit pixel. Thereafter, the buried conductive layer 22p may be formed, and an image sensor may be formed using the manufacturing method described with reference to FIGS. 9A to 14.

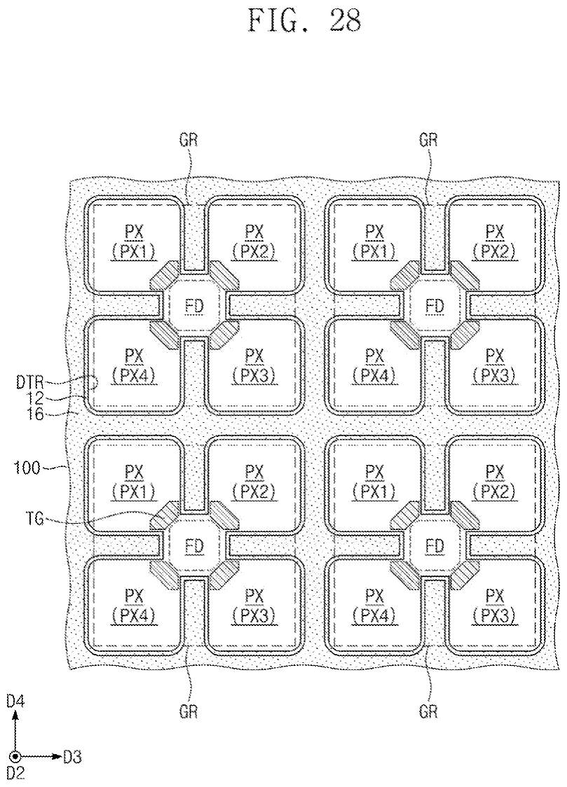

FIG. 28 is a plan view of an image sensor according to example embodiments. Referring to FIG. 28, first to fourth pixels PX1, PX2, PX3, and PX4 sequentially arranged in a clockwise direction may constitute one pixel group GR. A pixel isolation structure DTI may not be provided at a center of the pixel group GR. A floating diffusion region FD may be provided at the center of the pixel group GR. The first to fourth pixels PX1, PX2, PX3, and PX4 may share one floating diffusion region FD. Transfer gates TG may be provided to each of the first to fourth pixels PX1, PX2, PX3, and PX4. The transfer gates TG may be adjacent to the floating diffusion region FD. One color filter and one micro lens may be on one pixel group GR.

A plurality of pixel groups GR may be provided. The pixel isolation structure DTI may be between the pixel groups GR and between the unit pixels PX neighboring in third or fourth directions D3 and D4. Other structures and features may be the same/similar to those described above.

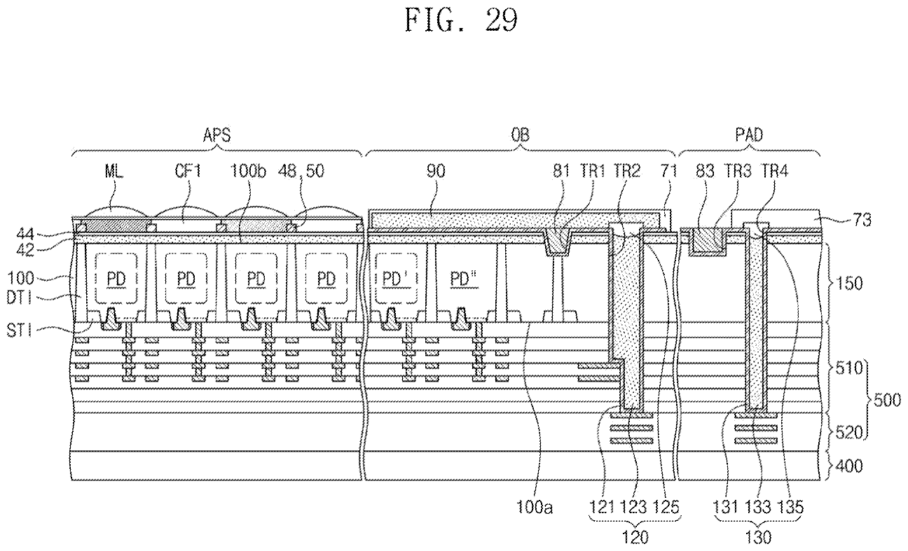

FIG. 29 is a cross-sectional view of an image sensor according to example embodiments. Referring to FIG. 29, a substrate 100 may include a pixel array region APS, an optical black region OB, and a pad region PAD. The substrate 100 may be a first substrate. A wiring layer 500 may be on a first surface 100a of the substrate 100 and a second substrate 400 may be on the wiring layer 500. The wiring layer 500 may include an upper wiring layer 510 and a lower wiring layer 520. The pixel array a region APS may include a plurality of unit pixels. The unit pixels may be substantially the same as those described with reference to FIGS. 3 to 28.

A first connection structure 120, a first conductive pad 81, and a bulk color filter 90 may be on the optical black region OB. The first connection structure 120 may include a first connection line 121, an insulating pattern 123, and a first capping pattern 125.

A portion of the first connection line 121 may be on a second surface 100b of the substrate 100. The first connection line 121 may pass through a photoelectric converter PD and the upper wiring layer 510 to connect the photoelectric converter PD and the wiring layer 500. The first connection line 121 may be connected to wirings in the upper wiring layer 510 and the lower wiring layer 520 through a second trench TR2, and may be connected to a pixel isolation structure DTI in the photoelectric converter PD through a first trench TR1 (in detail, to a buried conductive pattern 22 in FIG. 4A). Accordingly, the first connection structure 120 may be electrically connected to wirings in the wiring layer 500. The first connection line 121 may include a metal material, e.g., tungsten.

The first conductive pad 81 may be inside the first trench TR1 and may fill the remaining portion of the first trench TR1. The first conductive pad 81 may include a metal material, e.g., aluminum. The first conductive pad 81 may be connected to the buried conductive pattern 22 of FIG. 4A. A negative bias voltage may be applied to the buried conductive pattern 22 of FIG. 4A through the first conductive pad 81. This may prevent/reduce white spots or dark current problems.

The insulating pattern 123 may fill the remaining portion of the second trench TR2. The insulating pattern 123 may entirely or partially penetrate the photoelectric converter PD and the wiring layer 500. The first capping pattern 125 may be on the insulating pattern 123.

The bulk color filter 90 may be on the first conductive pad 81 and the first capping pattern 125. The bulk color filter 90 may cover the first conductive pad 81 and the first capping pattern 125. A bulk protective layer 71 may be on the bulk color filter 90, and may seal the bulk color filter 90.

A photoelectric conversion region PD′ and a dummy region PD″ may be in the optical black region OB of the substrate 100. The photoelectric conversion region PD′ may be doped with impurities of a second conductivity type (e.g., N-type) different from the first conductivity type (e.g., P-type). The photoelectric conversion region PD′ may have a structure similar to that of the photoelectric converter PD. The photoelectric conversion region PD′ may not perform the same operation (i.e., receive light and generate an electrical signal) as the photoelectric converter PD. The dummy region PD″ may not be doped with impurities. A signal generated in the dummy region PD″ may be used as information for removing process noise thereafter.

A second connection structure 130, a second conductive pad 83, and a pad region protective layer 73 may be in the pad region PAD. The second connection structure 130 may include a second connection line 131, an insulating pattern 133, and a second capping pattern 135.

The second connection line 131 may be on a second surface 100b of the substrate 100. The second connection line 131 may conformally cover inner walls of a third trench TR3 and a fourth trench TR4 while covering the second surface 100b. The second connection line 131 may pass through the photoelectric converter PD and the upper wiring layer 510 to connect the photoelectric converter PD and the wiring layer 500. The second connection line 131 may be connected to wiring in the lower wiring layer 520 through the fourth trench TR4. Accordingly, the second connection structure 130 may be electrically connected to wirings in the wiring layer 500. The second connection line 131 may include a metal material, e.g., tungsten.

The second conductive pad 83 may be inside the third trench TR3 and may fill the remaining portion of the third trench TR3. The second conductive pad 83 may include a metal material, e.g., aluminum. The second conductive pad 83 may serve as an electrical connection path to the outside of the image sensor device. The insulating pattern 133 may fill the remaining portion of the fourth trench TR4. The insulating pattern 133 may entirely or partially penetrate the photoelectric converter PD and the wiring layer 500. The second capping pattern 135 may be on the insulating pattern 133.

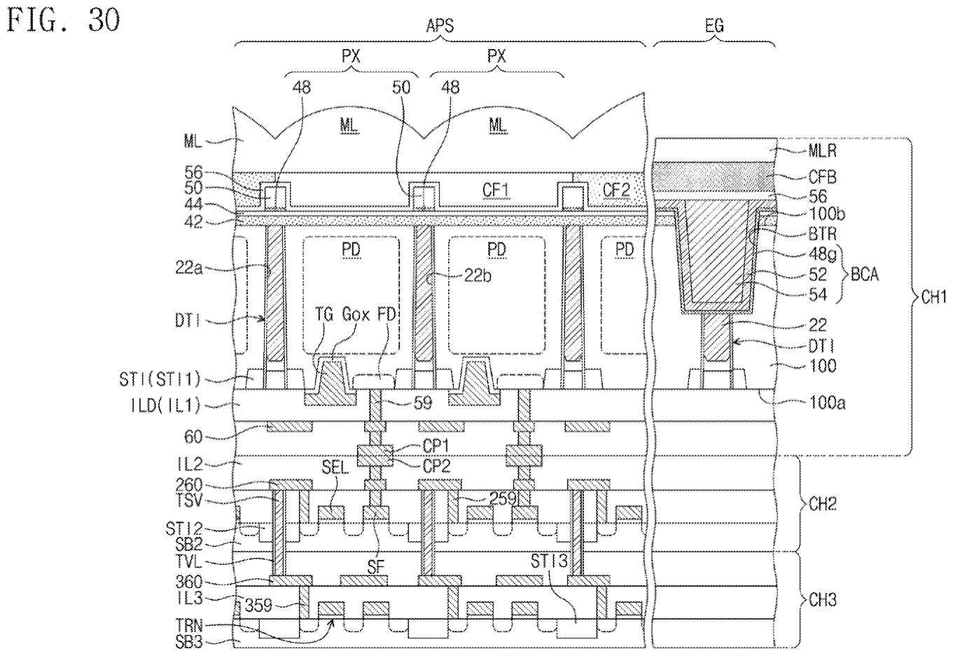

FIG. 30 is a cross-sectional view of an image sensor according to example embodiments. Referring to FIG. 30, a first sub-chip CH1, a second sub-chip CH2, and a third sub-chip CH3 may be sequentially bonded. The first sub-chip CH1 may perform an image sensing function. The first sub-chip CH1 may be the same as/similar to those described with reference to FIGS. 3 to 28.

The first sub-chip CH1 may include a substrate 100. The substrate 100 may be a first substrate. Transfer gates TG and first interlayer insulating layers IL1 covering the transfer gates TG may be on a first surface 100a of the substrate 100. The first interlayer insulating layers IL1 may be the interlayer insulating layers ILD described with reference to FIGS. 3 to 28. The substrate 100 may include a pixel array region APS and an edge region EG. The pixel array region APS may include a plurality of unit pixels. The edge region EG may correspond to a portion of the optical black region OB of FIG. 24.

A first device isolation structure STI1 may be on the substrate 100 and may define active regions. The first device isolation structure STI1 may be the same as/similar to the device isolation structure STI described with reference to FIGS. 3 to 28. The pixel isolation structure DTI may separate/define the unit pixels PX in the pixel array region APS of the first substrate 100. The pixel isolation structure DTI may extend to the edge region EG. The pixel isolation structure DTI may be the same as/similar to that described with reference to FIGS. 3 to 28.

The first interlayer insulating layers IL1 may cover the first surface 100a of the substrate 100. Wirings 60 may be in the first interlayer insulating layers IL1. The wirings 60 may be first wirings. A floating diffusion region FD may be connected to the wirings 60 through a first contact plug 59. A first conductive pad CP1 may be in the lowermost layer of the first interlayer insulating layers IL1. The first conductive pad CP1 may include copper.

A connection contact BCA may pass through a portion of a protective layer 44, a portion of a fixed charge layer 42, and a portion of the substrate 100 in the edge region EG and may come into contact with a buried conductive pattern 22. The protective layer 44 may be a first protective layer. The connection contact BCA may include an anti-diffusion pattern 48g conformally covering an inner wall of a back trench BTR, a first metal pattern 52 on the anti-diffusion pattern 48g, and a second metal pattern 54 filling the back trench BTR. The anti-diffusion pattern 48g may include, e.g., tungsten. The second metal pattern 54 may include aluminum. The anti-diffusion pattern 48g and the first metal pattern 52 may extend on the protective layer 44 and be electrically connected to other wirings or vias/contacts.

A second protective layer 56 may be on the protective layer 44. The second protective layer 56 may conformally cover a light blocking pattern 48, a low refractive index pattern 50, and the connection contact BCA.

A first optical black pattern CFB may be on the second protective layer 56 in the edge region EG. The first optical black pattern CFB may include, e.g., the same material as a blue color filter.

A lens residual layer MLR may be on the first optical black pattern CFB. The lens residual layer MLR may include the same material as that of a micro lenses ML.

The second sub-chip CH2 may include a second substrate SB2, select gate electrodes SEL between the second substrate SB2 and the first sub-chip CHL source follower gate electrodes SF, reset gates, and second interlayer insulating layers IL2 covering them. A second device isolation structure STI2 may be buried in the second substrate SB2 and may define active regions. Second contacts 259 and second wiring 260 may be in the second interlayer insulating layers IL2. A second conductive pad CP2 may be in the uppermost second interlayer insulating layer IL2. The second conductive pad CP2 may include copper. The second conductive pad CP2 may be in contact with the first conductive pad CP1. The source follower gate electrodes SF may be connected to the floating diffusion regions FD of the first sub-chip CH1, respectively.

The third sub-chip CH3 may include a third substrate SB3, peripheral transistors TRN between the third and second substrates SB3 and SB2, and third interlayer insulating layers IL3 covering them. A third device isolation structure STI3 may be buried in the third substrate SB3 and may define active regions. Third contacts 359 and third wiring 360 may be in the third interlayer insulating layers IL3. The uppermost third interlayer insulating layer IL3 may be in contact with the second substrate SB2. A through electrode TSV may pass through the second interlayer insulating layer IL2, the second device isolation structure STI2, the second substrate SB2, and the third interlayer insulating layer IL3, and may be connected to the second wiring 260 and The third wiring 360. A via insulating layer TVL may surround sidewalls of the through electrode TSV. The third sub-chip CH3 may include circuits for driving the first and/or second sub-chips CH1 and CH2 or storing electrical signals generated by the first and/or second sub-chips CH1 and CH2.

The portion of the buried conductive pattern may be oxidized, and thus the capping insulating pattern having the larger volume may be formed. The stress transmitted to the substrate may be controlled through the change in volume, and as a result, the warpage may be improved.

By way of summation and review, a CMOS image sensor is disclosed. In recent years, rapid development in the computer and communication industries has resulted in an increased demand for the image sensors with enhanced performances in a variety of fields such as digital cameras, camcorders, personal communication systems (PCS), gaming devices, security cameras, medical micro cameras. The image sensor may be categorized into a charge coupled device (CCD) type, and a complementary metal oxide semiconductor (CMOS) type. The CMOS image sensor is abbreviated as a CIS (CMOS image sensor). The CIS may include a plurality of two-dimensionally arranged pixels. Each of the plurality of pixels may include a photodiode (PD). The PD converts an incident light into an electric signal. The plurality of pixels may be defined by a deep isolation pattern disposed therebetween. An image sensor with improved warpage and a method manufacturing thereof.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An image sensor, comprising:
a substrate including a plurality of unit pixels and including a first surface facing a first direction and a second surface facing a second direction opposite to the first direction; and
a pixel isolation structure passing through the substrate in the second direction between the unit pixels,
wherein:
the pixel isolation structure includes:
a buried conductive pattern extending from the second surface of the substrate into an inside of the substrate; and
an insulating structure covering a lower surface of the buried conductive pattern and extending between the substrate and the buried conductive pattern,
a first level and a second level that is under the first level are defined,
the lower surface of the buried conductive pattern is positioned at the second level, and
a width of the insulating structure in a third direction parallel to the second surface of the substrate at the first level is smaller than that at the second level.

2. The image sensor as claimed in claim 1, wherein the buried conductive pattern includes a seam therein.

3. The image sensor as claimed in claim 1, wherein a width of the insulating structure in the third direction is substantially uniform at a level higher than the first level.

4. The image sensor as claimed in claim 1, wherein a width of the insulating structure in the third direction increases from the first level to the second level.

5. The image sensor as claimed in claim 1, wherein a width of the buried conductive pattern in the third direction at the first level is larger than that at the second level.

6. The image sensor as claimed in claim 1, wherein a width of the buried conductive pattern in the third direction is at a maximum at the first level.

7. The image sensor as claimed in claim 1, wherein the insulating structure includes an inner protrusion protruding toward an inside thereof from the lower surface of the buried conductive pattern.

8. The image sensor as claimed in claim 1, further comprising a conductive liner between the buried conductive pattern and the insulating structure.

9. The image sensor as claimed in claim 8, wherein the insulating structure further extends between the conductive liner and the buried conductive pattern.

10. The image sensor as claimed in claim 1, wherein the insulating structure includes silicon oxide.

11. An image sensor, comprising:
a substrate including a plurality of unit pixels and including a first surface facing a first direction and a second surface facing a second direction opposite to the first direction; and
a pixel isolation structure passing through the substrate in the second direction between the unit pixels,
wherein:
the pixel isolation structure includes:
a buried conductive pattern extending from the second surface of the substrate into an inside of the substrate; and
an insulating structure covering a lower surface of the buried conductive pattern and extending between the substrate and the buried conductive pattern,
the buried conductive pattern includes a first conductive portion and a second conductive portion under the first conductive portion, and
a width of the insulating structure in a third direction parallel to the second surface of the substrate is uniform on a side surface of the first conductive portion and increases on a side surface of the second conductive portion toward the first direction.

12. The image sensor as claimed in claim 11, wherein a width of the second conductive portion in the third direction decreases toward the first direction.

13. The image sensor as claimed in claim 11, wherein a width of the first conductive portion in the third direction decreases toward the second direction.

14. The image sensor as claimed in claim 11, wherein the insulating structure includes an inner protrusion protruding from the lower surface of the buried conductive pattern toward an inside thereof.

15. The image sensor as claimed in claim 11, further comprising a conductive liner between the buried conductive pattern and the insulating structure.

16. An image sensor, comprising:
a substrate including first to fourth pixels sequentially disposed in a clockwise direction, and including a first surface facing a first direction and a second surface facing a second direction opposite to the first direction; and
a pixel isolation structure passing through the substrate in the second direction between the first to fourth pixels,
wherein:
the pixel isolation structure includes:
conductive liners extending from the second surface of the substrate into the substrate and surrounding each of the first to fourth pixels; and
an insulating structure including a side portion extending between the substrate and each of the conductive liners,
a first level and a second level that is under the first level are defined,
a lower end of each of the conductive liners is located at the second level, and
a width of the side portion of the insulating structure in a third direction parallel to the second surface of the substrate at the first level is smaller than that at the second level.

17. The image sensor as claimed in claim 16, wherein the insulating structure further includes a buried portion extending into the substrate between the conductive liners.

18. The image sensor as claimed in claim 17, wherein the buried portion of the insulating structure is between the first pixel and the second pixel, between the second pixel and the third pixel, between the third pixel and the fourth pixel, and between the fourth pixel and the first pixel.

19. The image sensor as claimed in claim 16, wherein a width of the side portion of the insulating structure in the third direction increases from the first level to the second level.

20. The image sensor as claimed in claim 16, further comprising a buried conductive pattern extending from the second surface of the substrate to the inside of the substrate and between the first pixel and the third pixel and between the second pixel and the fourth pixel.
